(19) United States
(12) Patent Application Publication
(10) Pub. No.: US 2024/0336542 A1
(43) Pub. Date: Oct. 10, 2024

(54) ISOTOPIC POLYMER, COMPOSITION AND CHIP DEVICE CONTAINING THE SAME

(71) Applicant: Lextar Electronics Corporation, Hsinchu City (TW)

(72) Inventors: Yung Chuan CHUANG, Hsinchu City (TW); Wen Wan TAI, Hsinchu City (TW); Yu-Chun LEE, Hsinchu City (TW)

(21) Appl. No.: 18/624,628

(22) Filed: Apr. 2, 2024

Related U.S. Application Data
(60) Provisional application No. 63/458,365, filed on Apr. 10, 2023.

(30) Foreign Application Priority Data
Mar. 5, 2024 (TW) 113107869

(51) Int. Cl. C07B 59/00; C08L 63/00; C08L 83/08; H01L 25/075; H01L 33/50; H01L 33/56; H01L 33/58; H01L 33/62

(52) U.S. Cl. CPC C07B 59/004; C07B 59/001; C08L 63/00; C08L 83/08; H01L 25/0753; H01L 33/502; H01L 33/56; H01L 33/58; H01L 33/62; C07B 2200/05

(57) ABSTRACT

An isotopic polymer includes a silicone resin, an aromatic polymer, a modified silicone resin, a halogenated polysilane, an epoxy resin, or a combination thereof, wherein at least part of ¹²C, ¹H and/or ¹⁶O in the isotopic polymer is replaced with ¹⁴C, ³H and/or ¹⁵O. The decaying age of the isotopic polymer is less than 50,000 years.

### CROSS REFERENCE TO RELATED APPLICATIONS

This application claims priority of Taiwan Patent Application No. 113107869, filed on Mar. 5, 2024, and the benefit of U.S. Provisional Application No. 63/458,365, filed on Apr. 10, 2023, the entirety of which are incorporated by reference herein.

### TECHNICAL FIELD

The disclosure relates to a polymer, and, in particular, to an isotopic polymer.

### BACKGROUND

### Description of the Related Art

Synthetic materials made by processing fossil fuels are often used as packaging materials or structural materials, and are widely used in electronic products, electronic elements, and optoelectronic elements, for example, to improve the heat resistance, durability, and impact resistance of the final products and the elements thereof.

Despite the popularity, synthetic materials made from fossil fuels produce large amounts of carbon dioxide during their production. Carbon dioxide is one of the main greenhouse gases that exacerbate the greenhouse effect. There is therefore a need to provide a new polymer material that can reduce carbon dioxide emissions and lessen the impact on the environment.

### SUMMARY

In order to reduce carbon dioxide emissions, the present disclosure provides a new polymer material.

An embodiment of the present disclosure provides an isotopic polymer includes a silicone resin, an aromatic polymer, a modified silicone resin, a halogenated polysilane, an epoxy resin, or a combination thereof, wherein at least part of ¹²C, ¹H and/or ¹⁶O in the isotopic polymer is replaced with ¹⁴C, ³H and/or ¹⁵O. The decaying age of the isotopic polymer is less than 50,000 years.

An embodiment of the present disclosure provides a chip device comprising: a substrate; a chip disposed on the substrate; and a package structure for encapsulating the chip, wherein materials of the package structure and/or materials of the substrate comprise an isotopic polymer as described above.

In addition, an embodiment of the present disclosure provides a chip device comprising: a substrate; a chip disposed on the substrate; and a shading layer disposed on the substrate, wherein materials of the shading layer and/or materials of the substrate comprises an isotopic polymer as described above.

### BRIEF DESCRIPTION OF THE DRAWINGS

Embodiments of the present disclosure are described in detail below with the accompanying drawings. It should be noted that the various feature components are not drawn to scale and are used for illustrative examples only. In fact, the size of the components may be enlarged or reduced to clearly show technical features of the present disclosure embodiments.

FIG. 1 is a cross-sectional schematic view of a chip device according to an embodiment of the present disclosure.

FIG. 2 is a cross-sectional schematic view of a chip device according to an embodiment of the present disclosure.

FIG. 3 is a cross-sectional schematic view of a chip device according to an embodiment of the present disclosure.

FIG. 4A is a cross-sectional schematic view of a chip device according to an embodiment of the present disclosure.

FIG. 4B is a cross-sectional schematic view of a chip device according to FIG. 4A of an embodiment of the present disclosure.

FIG. 4C is a cross-sectional schematic view of a chip device according to FIG. 4A of another embodiment of the present disclosure.

FIG. 5 is a cross-sectional schematic view of a chip device according to an embodiment of the present disclosure.

FIG. 6 is a cross-sectional schematic view of a chip device according to an embodiment of the present disclosure.

### DETAILED DESCRIPTION

The following disclosures provide a number of different implementations or examples to implement different features of the disclosure. The following disclosure describes specific examples of the various components and their arrangement for simplicity. Of course, these specific examples are not intended to be limiting. For example, if an embodiment of the present disclosure describes a first feature component being formed above or on a second feature component, it means that it may include an embodiment in which the first feature component and the second feature component are in direct contact, or it may include an embodiment in which an additional feature component is formed between the first feature component and the second feature component, so that the first feature component and the second feature component may not be in direct contact.

It should be understood that additional operational steps may be implemented before, during or after the described method, and that in other embodiments of the described method, some of the operational steps may be replaced or omitted.

In addition, space-related terms such as “under”, “below”, “beneath”, “on”, “above”, “over”, etc. may be used in the disclosure. The space-related terms are intended to facilitate describing relationships between one element(s) or feature component(s) and another element(s) or feature component(s) in the drawings. The space-related terms include different orientations of the device in use or in operation, as well as the orientations depicted in the drawings. When the device is rotated to a different orientation (e.g., 90 degrees or other), the space-related terms used therein will also be interpreted according to the rotated orientation.

In the disclosure, terms “about,” “approximate,” or “substantially” usually indicates a value of a given value or range that varies within 20%, within 10%, within 5%, within 3%, within 2%, within 1%, or within 0.5%. The value given here are approximate value, i.e., “about,” “approximate,” or “substantially” may be implied without specifying “about,” “approximate,” or “substantially”. In the disclosure, the term “a−b” indicates a value which is greater than or equal to a and less than or equal to b.

Unless defined otherwise, all terms (including technical and scientific terms) used herein have the same meaning as commonly understood by one of ordinary skills in the art to which this disclosure belongs. It should be understood that terms, such as those defined in commonly used dictionaries, should be interpreted as having a meaning that conforms to the relative skills of the present disclosure and the background or the context of the present disclosure, and should not be interpreted in an idealized or overly formal manner unless so defined.

The same reference symbols and/or reference signs may be repeated in the different implementations disclosed below. These repetitions are for purposes of simplicity and clarity and are not intended to qualify a particular relationship between the different embodiments and/or structures discussed.

The term “C₁-C₃₀ alkyl group” used herein refers to a linear, branched, or cyclic aliphatic hydrocarbon monovalent group having 1 to 30 carbon atoms in the main carbon chain. Non-limiting examples of C₁-C₃₀ alkyl group include, but are not limited to, a methyl group, an ethyl group, a propyl group, an iso-butyl group, a sec-butyl group, a tert-butyl group, a pentyl group, an iso-amyl group, a hexyl group, a decyl group, a dodecyl group, a cyclohexyl group, a cyclooctyl group, and a cyclododecyl group. Similarly, the term “C₁-C₂₀ alkyl group” in the present disclosure refers to o a linear, branched, or cyclic aliphatic hydrocarbon monovalent group having 1 to 20 carbon atoms in the main carbon chain, specific examples thereof will not be repeated herein.

The term “C₁-C₃₀ alkylene group” used herein refers to a linear, branched, or cyclic aliphatic hydrocarbon divalent group having 1 to 30 carbon atoms in the main carbon chain. Non-limiting examples of C₁-C₃₀ alkylene group include, but are not limited to, a methylene group, an ethylene group, a propylene group, an iso-butylene group, a sec-butylene group, a tert-butylene group, a pentylene group, an iso-amylene group, a hexylene group, a decylene group, a dodecylene group, a cyclohexylene group, a cyclooctylene group, and a cyclododecylene group. Similarly, the term “C₁-C₂₀ alkylene group” in the present disclosure refers to o a linear, branched, or cyclic aliphatic hydrocarbon divalent group having 1 to 20 carbon atoms in the main carbon chain, specific examples thereof will not be repeated herein.

The term “C₂-C₃₀ alkenyl group” used herein refers to a linear, branched, or cyclic aliphatic hydrocarbon monovalent group having 2 to 30 carbon atoms and at least one carbon-carbon double bond in the main carbon chain. Non-limiting examples of C₂-C₃₀ alkenyl group include, but are not limited to, an ethenyl group, a propenyl group, an isobutenyl group, a sec-butenyl group, a tert-butenyl group, a pentenyl group, an isopentenyl group, a hexenyl group, a decenyl group, a dodecenyl group, a pentadecenyl group, a cyclohexenyl group, a cyclooctenyl group, a cyclopentenyl group, a cyclopentadienyl group, and a cyclopentadecenyl group. Similarly, the term “C₂-C₂₀ alkenyl group” in the present disclosure refers to a linear, branched, or cyclic aliphatic hydrocarbon monovalent group having 2 to 20 carbon atoms and at least one carbon-carbon double bond in the main carbon chain, specific examples thereof will not be repeated herein.

The term “C₂-C₃₀ alkynyl group” used herein refers to a linear, branched, or cyclic aliphatic hydrocarbon monovalent group having 2 to 30 carbon atoms and at least one carbon-carbon triple bond in the main carbon chain. Non-limiting examples of C₂-C₃₀ alkynyl group include, but are not limited to, an ethenyl group, a propynyl group, and a 2-butynyl group. Similarly, the term “C₂-C₂₀ alkynyl group” in the present disclosure refers to a linear, branched, or cyclic aliphatic hydrocarbon monovalent group having 2 to 30 carbon atoms and at least one carbon-carbon triple bond in the main carbon chain, specific examples thereof will not be repeated herein.

The term “amino group” in the present disclosure refers to a monovalent group having a structure shown as follows: —NH₂, —NHR^{a}, or —NR^{b}₂, wherein R^{a} and R^{b} may be a C₁-C₃₀ alkyl group, a C₂-C₃₀ alkenyl group, a C₂-C₃₀ alkynyl group, or an amine group. Non-limiting examples of the amine group include, but are not limited to, a methylamine group, an ethylamine group, an ethylenediamine group, a n-methyl pentyl amine group, an allylamine group, a propargylamine group, a triethylenetriamine group, a triethylenetetramine group, a tetraethylenepentamine group, a divinylpropylamine group, a polyamine group, an isophorondiamine group, a mesitylene diamine group, a 1,3-bis(aminomethyl)cyclohexyl group, a 1,2-cyclohexanediamine group, a hexanediamine group, a menthane diamine group, a N-aminoethylpiperazinyl group, a bis(4-amino-3-methylcyclohexyl) methane group, a bis(4-aminocyclohexyl) methane group, a diaminodiphenylmethane group, a diaminodiphenylsulfone group, a m-phenylenediamine group, a dicyandiamide group, and an adipic dihydrazide group.

The term “nitrogen-containing linking group” used herein refers to a linear, branched, or cyclic aliphatic hydrocarbon divalent group having a nitrogen atom (N). Non-limiting examples of the nitrogen-containing linking groups include, but are not limited to, linking groups derived from NH₃, a triethylenetriamine group, a triethylenetetramine group, a tetraethylenepentamine group, a divinylpropylamine group, a polyamine group, an isophorondiamine group, a mesitylene diamine group, a 1,3-bis(aminomethyl) cyclohexyl group, a 1,2-cyclohexanediamine group, a hexanediamine group, a menthane diamine group, a N-aminoethylpiperazinyl group, a bis(4-amino-3-methylcyclohexyl) methane group, a bis(4-aminocyclohexyl) methane group, a diaminodiphenylmethane group, a diaminodiphenylsulfone group, a m-phenylenediamine group, a dicyandiamide group, and an adipic dihydrazide group.

The term “sulfur-containing linking group” used herein refers to a linear, branched, or cyclic aliphatic hydrocarbon divalent group having a sulfur atom(S) therein. Non-limiting examples of the sulfur-containing linking groups include, but are not limited to, linking groups derived from thiols, thioethers, sulfide esters, sulfonic acids, sulfonate esters, and sulfonamides.

In this disclosure, a phrase “a proportion of the presence of 14C” indicates moles of ¹⁴C/moles of all C atoms X 100%. A phrase “a proportion of the presence of ³H” indicates moles of ³H/moles of all H atoms X 100%. A phrase “a proportion of the presence of ¹⁵O” indicates moles of ¹⁵O/moles of all O atoms X 100%.

An embodiment of the present disclosure provides an isotopic polymer including a silicone resin, an aromatic polymer, a modified silicone resin, a halogenated polysilane, an epoxy resin, or a combination thereof. At least part of ¹²C, ¹H and/or ¹⁶O in the isotopic polymer is replaced with ¹⁴C, ³H and/or ¹⁵O so that the decaying age of the isotopic polymer is less than 50,000 years.

The term “decaying age” of the isotopic polymer disclosed herein is calculated according to a decay law of the isotopes ¹⁴C, ³H, and ¹⁵O:

N=N₀*(1/2)^{t/T},

wherein N₀ is the number of nuclei of isotopes ¹⁴C, ³H, and ¹⁵O at an initial time (t=0), N is the number of the remaining nuclei of the isotopes ¹⁴C, ³H, and ¹⁵O after a decay time, t is the decay time, and T is the half-life of the isotopes. It should be noted that since the decay times of isotopes ¹⁴C, ³H, and ¹⁵O cannot be added up together, the “decaying times” of the isotopic polymers disclosed herein are mainly based on the calculation of ¹⁴C.

The isotopic polymer disclosed herein may be formed by polymerizing phenolic compounds, amine compounds, imidazole compounds, boron amine compounds or boron amine salt compounds, acid anhydride compounds, silicone-containing compounds, compounds having oxygen-containing heterocycles, or a combination thereof, in which at least part of ¹²C, ¹H and/or ¹⁶O in the isotopic polymer is replaced with ¹⁴C, ³H and/or ¹⁵O.

The term “phenolic compound” used herein refers to an aromatic compound in which a hydrogen atom on an aromatic hydrocarbon ring is replaced with a hydroxyl group. Non-limiting examples of the phenolic compounds include, but are not limited to, a phenol, a phenol methane, a 2,6-di butyl-p-cresol, a cresol, a xylenol, a polyphenol, and a 3-pentadecylphenol.

Non-limiting examples of the amine compounds include, but are not limited to, a triethylenetriamine, a triethylenetetramine, a tetraethylenepentamine, a divinylpropylamine, a polyamine, an isophorondiamine, a mesitylene diamine, a 1,3-bis(aminomethyl) cyclohexane, a 1,2-cyclohexanediamine, a hexanediamine, a menthane diamine, a N-aminoethylpiperazine, a bis(4-amino-3-methylcyclohexyl) methane, a bis(4-aminocyclohexyl) methane, a diaminodiphenylmethane, a diaminodiphenylsulfone, a m-phenylenediamine, a dicyandiamide, an adipic dihydrazide, and tertiary amine compounds.

Non-limiting examples of the tertiary amine compounds include, but are not limited to, straight-chain diamines, straight-chain tertiary amines, tetramethylamines, tertiary alkyl monoamines, triethanolamines, piperidines, N,N-dimethylpiperazines, triethylenediamines, pyridines, methylpiperidines, 1,8-dichlorobicyclo(5,4,0)-7-undecenylenes, benzyldimethylamines, 2-(dimethylaminomethyl) phenol, 2,4,5-trimethylaminomethylphenol, tris-2-ethylhexanoate, and the like.

Non-limiting examples of imidazole compounds in the present disclosure include, but are not limited to, a 2-methylimidazole, a 2-ethyl-4-methylimidazole, a 2-undecylimidazole, a 2-heptadecylimidazole, a 2-phenylimidazole, a 1-phenylmethyl-2-methylimidazole, a 1-cyanoethyl-2-methylimidazole, a 1-cyanoethyl-2-ethyl-4-methylimidazole, a 1-cyanoethyl-2-undecylimidazole, and 1-cyanoethyl-2-undecyl-imidazole trimellitates.

Non-limiting examples of boron amine compounds or boron amine salt compounds include, but are not limited to, a boron trifluoride-n-butylamine, a boron trifluoride-monoethylamine, a boron trifluoride-benzylamine, and a boron trifluoride-dimethylaniline. Non-limiting examples of acid anhydride compounds of the present disclosure include, but are not limited to, a phthalic anhydride, a tetrahydrophthalic anhydride, a hexahydrophthalic anhydride, a methyl tetrahydrophthalic anhydride, a methyl hexahydrophthalic anhydride, a nadic methyl anhydride, a dodecylsuccinic anhydride, a chlorendic anhydride, a pyromellitic dianhydride, a benzophenonetetracarboxylic dianhydride, a cyclohexanetetrcarboxylic dianhydride, a diphenyl ether tetracarboxylic acid dianhydride, a trimellitic anhydride and a polyazelaic polyanhydride.

Non-limiting examples of the silicone-containing compounds in the present disclosure include, but are not limited to, halosilanes, silanes, siloxanes, silicone resins, modified silicones, and the like. The silanes include alkoxysilanes, hydrosilanes, silanols, silanol salts, acyloxysilanes, aminosilanes, acylamino-silanes, isopropoxy-silanes, chain-alkenylsilanes, fluorohydrocarbon silanes, chlorohydrocarbon silanes, bromohydrocarbon silanes, cyanohydrocarbon silanes, isocyanato-hydrocarbon silanes, hydroxyhydrocarbon silanes, ammohydrocarbon silanes, cyclic hydrocarbon silanes, methylacryloxy-silanes, azide- and diazoalkydrocarbon silanes.

The term “oxygen-containing heterocycle” disclosed herein refers to a ring group having an oxygen atom as a ring-forming atom. Non-limiting examples of the compounds having oxygen-containing heterocycles include, but are not limited to, glycidyl ether compounds, glycidyl ester compounds, glycidyl amine compounds, alicyclic epoxy compounds, epoxidized olefins, and new epoxy resins. The glycidyl ether compounds include bisphenol A epoxy resins, bisphenol F epoxy resins, bisphenol S epoxy resins, hydrogenated bisphenol A epoxy resins, phenol phenolic epoxy resins, cresol phenolic epoxy resins, phenolic epoxy resins, aliphatic glycidyl ether resins, or brominated epoxy resins.

The isotopic polymers of the present disclosure may include a silicone resin, an aromatic polymer, a modified silicone resin, a halogenated polysilane, or an epoxy resin in which at least part of ¹²C, ¹H and/or ¹⁶O in the isotopic polymer is replaced with ¹⁴C, ³H and/or ¹⁵O.

The aromatic polymer in the present disclosure refers to a polymer comprising a benzene ring or other aromatic ring.

Non-limiting examples of modified silicone resins in the present disclosure include, but are not limited to, alkyd-modified silicone resins, polyester-modified silicone resins, acrylic-modified silicone resins, epoxy-modified silicone resins, phenolic-modified silicone resins, and siloxane-modified polyimide resins.

In some embodiments, the isotopic polymers of the present disclosure are formed by polymerizing at least one isotopic monomer having a main structure represented by one of the following Formulae 1 to 7, and wherein at least part of ¹²C, ¹H and/or ¹⁶O in the isotopic polymer is replaced with ¹⁴C, ³H and/or ¹⁵O:

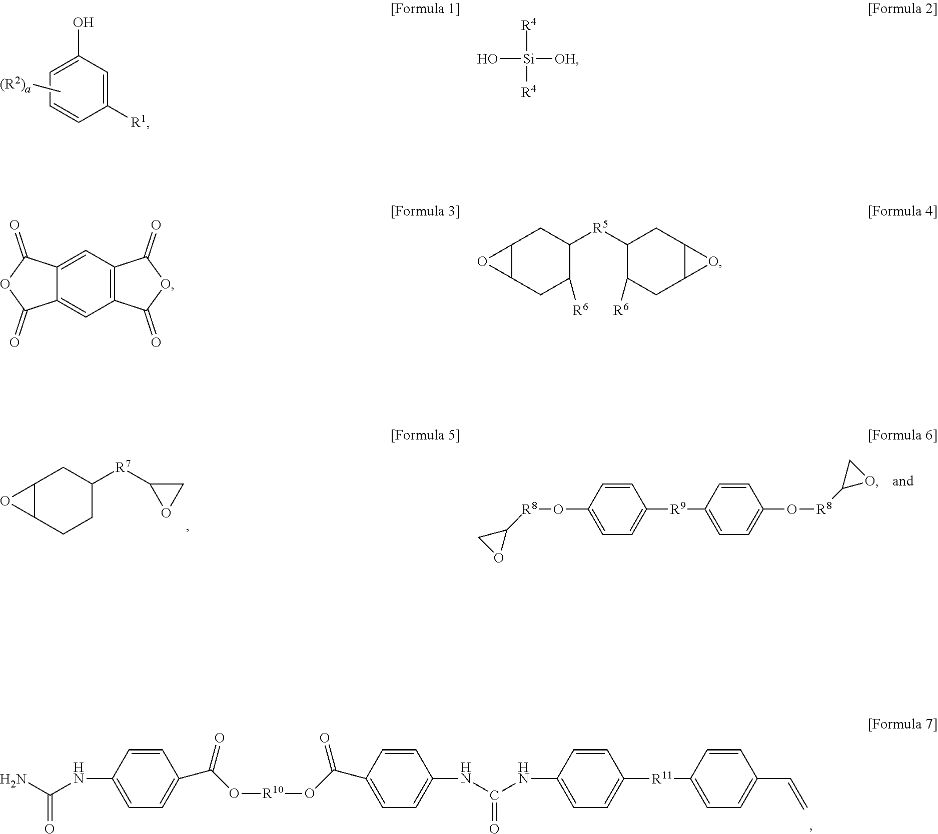

wherein R¹ is a C₁-C₃₀ alkyl group, a C₂-C₃₀ alkenyl group, or a C₂-C₃₀ alkynyl group;
R² is OH, a C₁-C₃₀ alkyl group, an amine group, a C₁-C₃₀ alkyl group substituted with an amine group, or a C₂-C₃₀ alkenyl group;
a is an integer selected from 1 to 4;
R⁴ is a phenyl group, a phenyl group substituted with a C₁-C₃₀ alkyl group, or a C₁-C₃₀ alkyl group;
R⁵ is —COOCH₂— or a C₁-C₃₀ alkylene group;
R⁶ is a C₁-C₃₀ alkyl group;
R⁷ is a C₁-C₂₀ alkylene group;
R⁸ is a nitrogen-containing linking group or a C₁-C₂₀ alkylene group;
R⁹ is a sulfur-containing linking group or a C₁-C₂₀ alkylene group;
R¹⁰ is a C₁-C₂₀ alkylene group;
R¹¹ is an oxy group, a sulfur-containing linking group, or a C₁-C₂₀ alkylene group, wherein at least one R² is selected from a linear or a branched C₂-C₂₀ alkenyl group, and wherein R² may be the same as or different from the other R² when a is greater than or equal to 2.

The ¹²C, ¹H and/or ¹⁶O in R¹, R², R⁴, R⁵, R⁶, R⁷, R⁸, R⁹, R¹⁰, and/or R¹¹ may be replaced with ¹⁴C, ³H and/or ¹⁵O or other ¹²C, ¹H and/or ¹⁶O in Formulae 1 to 7 may be replaced with ¹⁴C, ³H and/or ¹⁵O. For example, in some embodiments, the ¹²C replaced with ¹⁴C may be a ring carbon atom in Formula 1 or the ¹H replaced with ³H may be a hydrogen atom on a ring carbon atom in Formula 1.

In Formula 1, R¹ may be a C₁-C₂₀ alkyl group. In some embodiments, examples of R¹ may include a methyl group, an ethyl group, a propyl group, a butyl group, a pentyl group, a hexyl group, a heptyl group, an octyl group, an undecyl group, a tridecyl group, a tetradecyl group, a pentadecyl group, or a group derived from (CH)₄(CH₂)₈CH₃, (CH)₄(CH₂)₁₂CH₃, (CH)₂(CH₂)₁₂CH₃, (CH)₄(CH₂)₁₀CH₃, (CH)₄(CH₂)₁₄CH₃, (CH)₅(CH₂)₁₀, (CH)₃(CH₂)₁₆, and (CH)₅(CH₂)₈, but the disclosure is not limited thereto.

In Formula 1, R² may be OH, a C₁-C₂₀ alkyl group, an amine group, a C₁-C₂₀ alkyl group substituted with an amine group, or a C₂-C₂₀ alkenyl group. In some embodiments, R² may include OH, a methyl group, or a linear C₂-C₂₀ alkenyl group. In some embodiments, R² may include a C₁-C₅ alkyl group. In some embodiments, R² may include-NH₂, a triethylenetriamine group, a triethylenetetramine group, a tetraethylenepentamine group, a divinylpropylamine group, a polyamine group, an isophorondiamine group, a mesitylene diamine group, a 1,3-bis(aminomethyl) cyclohexyl group, a 1,2-cyclohexanediamine group, a hexanediamine group, a menthane diamine group, a N-aminoethylpiperazinyl group, a bis(4-amino-3-methylcyclohexyl) methane group, a bis(4-aminocyclohexyl) methane group, a diaminodiphenylmethane group, a diaminodiphenylsulfone group, a m-phenylenediamine group, a dicyandiamide group, and an adipic dihydrazide group, but the present disclosure is not limited thereto. In some embodiments, at least part of ¹²C and/or ¹H in R¹ may be replaced with ¹⁴C and/or ³H, but the present disclosure is not limited thereto. In some embodiments, at least part of ¹²C, ¹H and/or ¹⁶O in R² may be replaced with ¹⁴C, ³H and/or ¹⁵O, but the present disclosure is not limited thereto. In some embodiments, none of ¹²C and/or ¹H in R¹ may be replaced with ¹⁴C and/or ³H, and at least part of ¹²C, ¹H and/or ¹⁶O in R² may be replaced with ¹⁴C, ³H and/or ¹⁵O. In some embodiments, at least part of ¹²C and/or ¹H in R¹ may be replaced with ¹⁴C and/or ³H, and none of ¹²C, ¹H and/or ¹⁶O in R² may be replaced with ¹⁴C, ³H and/or ¹⁵O.

In Formula 2, R⁴ may be a phenyl group, a phenyl group substituted with a C₁-C₂₀ alkyl group, or a C₁-C₂₀ alkyl group. In some embodiments, R⁴ may be a phenyl group, a phenyl group substituted with a C₁-C₅ alkyl group, or a C₁-C₅ alkyl group. In some embodiments, at least part of ¹²C and/or ¹H in R⁴ may be replaced with ¹⁴C and/or ³H, but the present disclosure is not limited thereto. In some embodiments, at least part of ¹H and/or ¹⁶O in OH of Formula 2 is replaced with ³H and/or ¹⁵O, and none of ¹²C and/or ¹H in R⁴ of Formula 2 may be replaced with ¹⁴C and/or ³H. In some embodiments, none of ¹H and/or ¹⁶O in OH of Formula 2 is replaced with ³H and/or ¹⁵O, and at least part of ¹²C and/or ¹H in R⁴ may be replaced with ¹⁴C and/or ³H.

In Formula 4, R⁵ may be —COOCH₂— or a C₁-C₂₀ alkylene group. In some embodiments, R⁵ may be —COOCH₂— or a C₁-C₅ alkylene group. In some embodiments that R⁵ is —COOCH₂—, at least part of ¹²C, ¹H and/or ¹⁶O in R⁵ may be replaced with ¹⁴C, ³H and/or ¹⁵O. In some embodiments that R⁵ is a C₁-C₂₀ alkylene group or a C₁-C₅ alkylene group, at least part of ¹²C and/or ¹H in R⁵ may be replaced with ¹⁴C and/or ³H, but this disclosure is not limited thereto. In Formula 4, R⁶ may be a C₁-C₂₀ alkyl group. In some embodiments, R⁶ may be a C₁-C₅ alkyl group. In some embodiments, at least part of ¹²C and/or ¹H in R⁶ may be replaced with ¹⁴C and/or ³H, but this disclosure is not limited thereto. In some embodiments, none of ¹²C, ¹H and/or ¹⁶O in R⁵ may be replaced with ¹⁴C, ³H and/or ¹⁵O, and at least a portion of ¹²C and/or ¹H in R⁶ may be replaced with ¹⁴C and/or ³H. In some embodiments, at least part of ¹²C, ¹H and/or ¹⁶O in R⁵ may be replaced with ¹⁴C, ³H and/or ¹⁵O, and none of ¹²C and/or ¹H in R⁶ may be replaced with ¹⁴C and/or ³H. In some embodiments, at least part of the ¹²C, ¹H and/or ¹⁶O other than that in R⁵ or R⁶ in Formula 4 may be replaced with ¹⁴C, ³H and/or ¹⁵O, ¹²C, ¹H and/or ¹⁶O in R⁵ may not be replaced with ¹⁴C, ³H and/or ¹⁵O, and ¹²C and/or ¹H in R⁶ may not be replaced with ¹⁴C and/or ³H. In some embodiments, at least part of the ¹²C, ¹H and/or ¹⁶O other than that in R⁵ or R⁶ in Formula 4 may be replaced with ¹⁴C, ³H and/or ¹⁵O, at least part of ¹²C, ¹H and/or ¹⁶O in R⁵ may be replaced with ¹⁴C, ³H and/or ¹⁵O, and at least part of ¹²C and/or ¹H in R⁶ may be replaced with ¹⁴C and/or ³H. For example, in some embodiments, at least part of ¹²C, ¹H and/or ¹⁶O in the epoxycyclohexyl group of Formula 4 may be replaced with ¹⁴C, ³H and/or ¹⁵O, ¹²C, ¹H and/or ¹⁶O in R⁵ may not be replaced with ¹⁴C, ³H and/or ¹⁵O, and ¹²C and/or ¹H in R⁶ may not be replaced with ¹⁴C and/or ³H.

In Formula 5, R⁷ may be a C₁-C₂₀ alkylene group. In some embodiments, R⁷ may be a C₁-C₅ alkylene group. In some embodiments, ¹²C and/or ¹H in R⁷ may be replaced with ¹⁴C and/or ³H, but the present disclosure is not limited thereto. In some embodiments, at least part of ¹²C, ¹H and/or ¹⁶O other than that in R⁷ in Formula 5 may be replaced with ¹⁴C, ³H and/or ¹⁵O, and ¹²C and/or ¹H in R⁷ may not be replaced with ¹⁴C and/or ³H. In some embodiments, at least part of ¹²C, ¹H and/or ¹⁶O other than that in R⁷ in Formula 5 may be replaced with ¹⁴C, ³H and/or ¹⁵O, and at least part of ¹²C and/or ¹H in R⁷ may be replaced with ¹⁴C and/or ³H. For example, in some embodiments, at least part of ¹²C, ¹H and/or ¹⁶O in the epoxycyclohexyl group of Formula 5 may be replaced with ¹⁴C, ³H and/or ¹⁵O, and ¹²C and/or ¹H in R⁷ may not be replaced with ¹⁴C and/or ³H.

In Formula 6, R⁸ may be a nitrogen-containing linking group or a C₁-C₅ alkylene group. In some embodiments, the nitrogen-containing linking group may be a linking group derived from NH₃, a triethylenetriamine group, a triethylenetetramine group, a tetraethylenepentamine group, a divinylpropylamine group, a polyamine group, an isophorondiamine group, a mesitylene diamine group, a 1,3-bis(aminomethyl) cyclohexyl group, a 1,2-cyclohexanediamine group, a hexanediamine group, a menthane diamine group, a N-aminoethylpiperazinyl group, a bis(4-amino-3-methylcyclohexyl) methane group, a bis(4-aminocyclohexyl) methane group, a diaminodiphenylmethane group, a diaminodiphenylsulfone group, a m-phenylenediamine group, a dicyandiamide group, and an adipic dihydrazide group. In some embodiments, ¹²C and/or ¹H in R⁸ may be replaced with ¹⁴C and/or ³H, but the present disclosure is not limited thereto. In Formula 6, R⁹ may be a sulfur-containing linking group or a C₁-C₅ alkylene group. In some embodiments, the sulfur-containing linking group may be a linking group derived from thiols, thioethers, sulfide esters, sulfonic acids, sulfonate esters, and sulfonamides. In some embodiments, ¹²C, ¹H and/or ¹⁶O in R⁹ may be replaced with ¹⁴C, ³H and/or ¹⁵O, but the present disclosure is not limited thereto. In some embodiments, ¹²C and/or ¹H in R⁸ may not be replaced with ¹⁴C and/or ³H, and at least part of ¹²C and/or ¹H in R⁹ may be replaced with ¹⁴C and/or ³H. In some embodiments, at least part of ¹²C and/or ¹H in R⁸ may be replaced with ¹⁴C and/or ³H, and ¹²C and/or ¹H in R⁹ may not be replaced with ¹⁴C and/or ³H. In some embodiments, at least part of ¹²C, ¹H and/or ¹⁶O other than that in R⁸ or R⁹ in Formula 6 may be replaced with ¹⁴C, ³H and/or ¹⁵O, ¹²C and/or ¹H in R⁸ may not be replaced with ¹⁴C and/or ³H, and ¹²C and/or ¹H in R⁹ may not be replaced with ¹⁴C and/or ³H. In some embodiments, at least part of ¹²C, ¹H and/or ¹⁶O other than that in R⁸ or R⁹ in Formula 6 may be replaced with ¹⁴C, ³H and/or ¹⁵O, at least part of ¹²C and/or ¹H in R⁸ may be replaced with ¹⁴C and/or ³H, and at least part of ¹²C and/or ¹H in R⁹ may be replaced with ¹⁴C and/or ³H. For example, in some embodiments, at least part of ¹²C and/or ¹H in the benzene ring of Formula 6 may be replaced with ¹⁴C and/or ³H, ¹²C and/or ¹H in R⁸ may not be replaced with ¹⁴C and/or ³H, and ¹²C and/or ¹H in R⁹ may not be replaced with ¹⁴C and/or ³H.

In Formula 7, R¹⁰ may be a C₁-C₂₀ alkylene group. In some embodiment, R¹⁰ may be a C₁-C₅ alkylene group. In some embodiments, ¹²C and/or ¹H in R¹⁰ may be replaced with ¹⁴C and/or ³H, but the present disclosure is not limited thereto. In some embodiment, R¹¹ may be an oxy group, a sulfur-containing linking group, or a C₁-C₅ alkylene group. In some embodiments, the sulfur-containing linking group may be a linking group derived from thiols, thioethers, sulfide esters, sulfonic acids, sulfonate esters, and sulfonamides. In some embodiments, ¹²C, ¹H and/or ¹⁶O in R¹¹ may be replaced with ¹⁴C, ³H and/or ¹⁵O, but the present disclosure is not limited thereto. In some embodiments, ¹²C and/or ¹H in R¹⁰ may not be replaced with ¹⁴C and/or ³H, and at least part of ¹²C, ¹H and/or ¹⁶O in R¹¹ may be replaced with ¹⁴C, ³H and/or ¹⁵O. In some embodiments, at least part of ¹²C and/or ¹H in R¹⁰ may be replaced with ¹⁴C and/or ³H, and ¹²C, ¹H and/or ¹⁶O in R¹¹ may not be replaced with ¹⁴C, ³H and/or ¹⁵O. In some embodiments, at least part of ¹²C, ¹H and/or ¹⁶O other than that in R¹⁰ or R¹¹ in Formula 7 may be replaced with ¹⁴C, ³H and/or ¹⁵O, ¹²C and/or ¹H in R¹⁰ may not be replaced with ¹⁴C and/or ³H, and ¹²C, ¹H and/or ¹⁶O in R¹¹ may not be replaced with ¹⁴C, ³H and/or ¹⁵O. In some embodiments, at least part of ¹²C, ¹H and/or ¹⁶O other than that in R¹⁰ or R¹¹ in Formula 7 may be replaced with ¹⁴C, ³H and/or ¹⁵O, at least part of ¹²C and/or ¹H in R¹⁰ may be replaced with ¹⁴C and/or ³H, and at least part of ¹²C, ¹H and/or ¹⁶O in R¹¹ may be replaced with ¹⁴C, ³H and/or ¹⁵O. For example, in some embodiments, at least part of ¹²C and/or ¹H in the benzene ring of Formula 7 may be replaced with ¹⁴C and/or ³H, ¹²C and/or ¹H in R¹⁰ may not be replaced with ¹⁴C and/or ³H, and ¹²C, ¹H and/or ¹⁶O in R¹¹ may not be replaced with ¹⁴C, ³H and/or ¹⁵O.

In some embodiments, the isotopic polymer of the present disclosure may include an isotopic homopolymer formed by polymerizing one isotopic monomer among the isotopic monomers of Formula 1 to Formula 7 above, but the present disclosure is not limited thereto. In some embodiments, the isotopic polymers of the present disclosure may include an isotopic copolymer formed by polymerizing at least two isotopic monomers among the isotopic monomers of Formula 1 to Formula 7 above. In some embodiments, the isotopic polymer of the present disclosure may include an isotopic copolymer formed by polymerizing at least one isotopic monomer among the isotopic monomers of Formula 1 to Formula 7 described above and other monomer. For example, the isotopic polymer of the present disclosure may be formed by polymerizing at least one isotopic monomer having a main structure represented by one of Formulae 4 to 6 above, wherein at least part of the ¹²C, ¹H and/or ¹⁶O in the main structure is replaced with ¹⁴C, ³H and/or ¹⁵O, and an isotopic monomer having a main structure represented by Formula 3 above, wherein at least part of the ¹²C, ¹H and/or ¹⁶O in the main structure is replaced with ¹⁴C, ³H and/or ¹⁵O. For another example, the isotopic polymer of the present disclosure may be formed by polymerizing at least one isotopic monomer having a main structure represented by one of Formulae 4 to 6 above, wherein the main structure does not include ¹⁴C, ³H and/or ¹⁵O, and an isotopic monomer having a main structure represented by Formula 3 above, wherein at least part of the ¹²C, ¹H and/or ¹⁶O in the main structure is replaced with ¹⁴C, ³H and/or ¹⁵O. In some embodiments, the isotopic polymer of the present disclosure may be formed by polymerizing at least one isotopic monomer having a main structure represented by one of Formulae 4 to 6 above, wherein at least part of the ¹²C, ¹H and/or ¹⁶O in the main structure is replaced with ¹⁴C, ³H and/or ¹⁵O, and an isotopic monomer having a main structure represented by Formula 3 above, wherein the main structure does not include ¹⁴C, ³H and/or ¹⁵O.

In some embodiments, the isotopic polymer of the present disclosure may be formed by polymerizing an isotopic monomer having a main structure represented by Formula 6 above, wherein at least part of the ¹²C, ¹H and/or ¹⁶O in the main structure is replaced with ¹⁴C, ³H and/or ¹⁵O, and an isotopic monomer having a main structure represented by Formula 2 above, wherein at least part of the ¹²C, ¹H and/or ¹⁶O in the main structure is replaced with ¹⁴C, ³H and/or ¹⁵O. In some embodiments, the isotopic polymer of the present disclosure may be formed by polymerizing an isotopic monomer having a main structure represented by Formula 6 above, wherein the main structure does not include ¹⁴C, ³H and/or ¹⁵O, and an isotopic monomer having a main structure represented by Formula 2 above, wherein at least part of the ¹²C, ¹H and/or ¹⁶O in the main structure is replaced with ¹⁴C, ³H and/or ¹⁵O. In some embodiments, the isotopic polymer of the present disclosure may be formed by polymerizing an isotopic monomer having a main structure represented by Formula 6 above, wherein at least part of the ¹²C, ¹H and/or ¹⁶O in the main structure is replaced with ¹⁴C, ³H and/or ¹⁵O, and an isotopic monomer having a main structure represented by Formula 2 above, wherein the main structure does not include ¹⁴C, ³H and/or ¹⁵O.

In some embodiments, the isotopic polymer of the present disclosure may be formed by polymerizing an isotopic monomer having a main structure represented by Formula 6 above, wherein at least part of the ¹²C, ¹H and/or ¹⁶O in the main structure is replaced with ¹⁴C, ³H and/or ¹⁵O, and an isotopic monomer having a main structure represented by Formula 1 above, wherein at least part of the ¹²C, ¹H and/or ¹⁶O in the main structure is replaced with ¹⁴C, ³H and/or ¹⁵O. In some embodiments, the isotopic polymer of the present disclosure may be formed by polymerizing an isotopic monomer having a main structure represented by Formula 6 above, wherein the main structure does not include ¹⁴C, ³H and/or ¹⁵O, and an isotopic monomer having a main structure represented by Formula 1 above, wherein at least part of the ¹²C, ¹H and/or ¹⁶O in the main structure is replaced with ¹⁴C, ³H and/or ¹⁵O. In some embodiments, the isotopic polymer of the present disclosure may be formed by polymerizing an isotopic monomer having a main structure represented by Formula 6 above, wherein at least part of the ¹²C, ¹H and/or ¹⁶O in the main structure is replaced with ¹⁴C, ³H and/or ¹⁵O, and an isotopic monomer having a main structure represented by Formula 1 above, wherein the main structure does not include ¹⁴C, ³H and/or ¹⁵O.

In some embodiments, the isotopic polymer of the present disclosure has a main structure represented by the following Formula I, and at least part of the ¹²C, ¹H and/or ¹⁶O in the main structure is replaced with ¹⁴C, ³H and/or ¹⁵O:

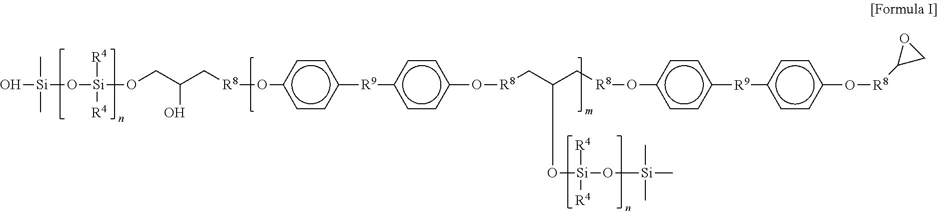

wherein n is an integer selected from 1 to 1,000,000;
m is an integer selected from 1 to 1,000,000;
R⁴, R⁸, and R⁹ are defined as described above.

In some embodiments, the isotopic polymer of the present disclosure has a main structure represented by the following Formula II, and at least part of the ¹²C, ¹H and/or ¹⁶O in the main structure is replaced with ¹⁴C, ³H and/or ¹⁵O:

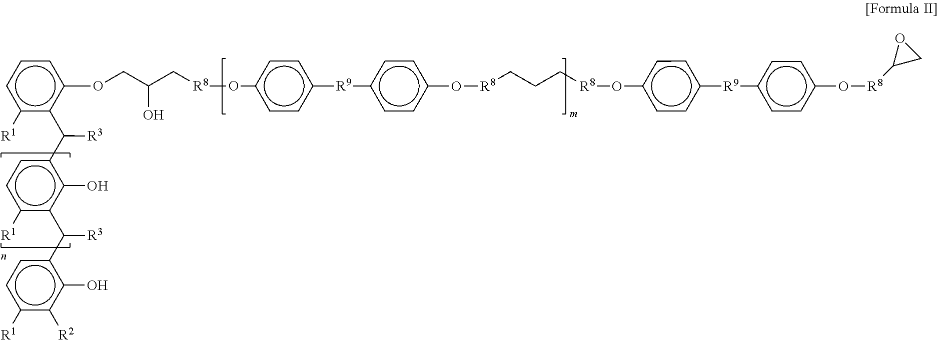

wherein n is an integer selected from 1 to 1,000,000;
m is an integer selected from 1 to 1,000,000;
R¹, R⁸, and R⁹ are defined as described above.

In some embodiments, the isotopic polymer of the present disclosure may include one isotopic repeating unit. The isotopic repeating unit has a repeating unit main structure represented by one of the following Formulae 8 to 12, and at least part of the ¹²C, ¹H and/or ¹⁶O in the repeating unit main structure is replaced with ¹⁴C, ³H and/or ¹⁵O:

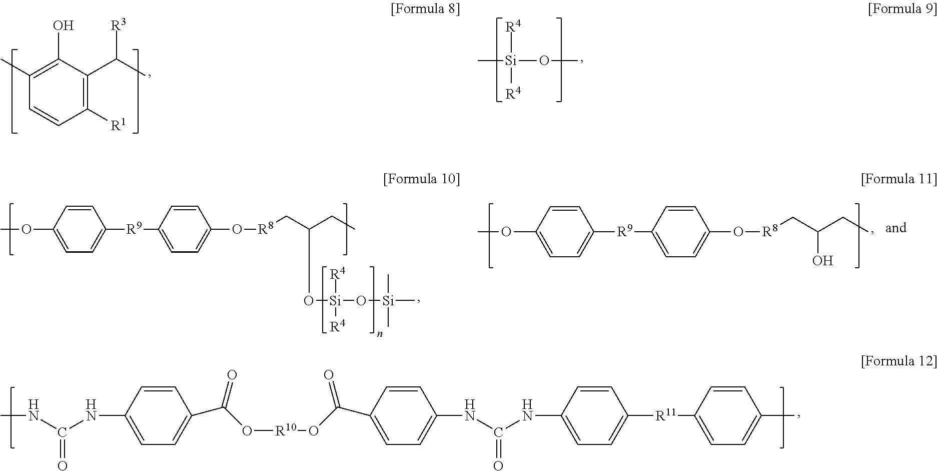

wherein R³ is a C₁-C₂₉ alkyl group, the definitions of R¹, R⁴, R⁸, R⁹, R¹⁰, and R¹¹ are the same as the definitions of R¹, R⁴, R⁸, R⁹, R¹⁰, and R¹¹ in Formula 1 to Formula 7 above, and therefore will not be repeated herein.

In some embodiments, R³ may be a C₁-C₂₀ alkyl group. In some embodiments, R³ may be a C₁-C₅ alkyl group. In some embodiments, ¹²C and/or ¹H in R³ may be replaced with ¹⁴C and/or ³H, but the present disclosure is not limited thereto. In some embodiments, at least part of ¹²C, ¹H and/or ¹⁶O other than that in R³ in Formula 8 may be replaced with ¹⁴C, ³H and/or ¹⁵O, and ¹²C and/or ¹H in R³ may not be replaced with ¹⁴C and/or ³H. In some embodiments, at least part of ¹²C, ¹H and/or ¹⁶O other than that in R³ in Formula 8 may be replaced with ¹⁴C, ³H and/or ¹⁵O, and at least part of ¹²C and/or ¹H in R³ may be replaced with ¹⁴C and/or ³H. For example, in some embodiments, at least part of ¹²C, ¹H and/or ¹⁶O in the phenol group of Formula 8 may be replaced with ¹⁴C, ³H and/or ¹⁵O, and ¹²C and/or ¹H in R³ may not be replaced with ¹⁴C and/or ³H.

In some embodiments, a sum of a proportion of the presence of ¹⁴C, a proportion of the presence of ³H, and a proportion of the presence of ¹⁵O in the isotopic polymer of the present disclosure is in a range from 0.1% to 100%. In some embodiments, the sum of the proportion of the presence of ¹⁴C, the proportion of the presence of ³H, and the proportion of the presence of ¹⁵O in the isotopic polymer of the present disclosure is in the range of 0.5% to 75%. In some embodiments, in the isotopic polymer of the present disclosure, the proportion of the presence of ¹⁴C is greater than the proportion of the presence of ³H and/or the proportion of the presence of ¹⁵O.

Further, the isotopic polymer of the present disclosure includes biomass materials (e.g., from natural plant extracts), so that at least part of ¹²C, ¹H and/or ¹⁶O in the isotopic polymer of the present disclosure is replaced with ¹⁴C, ³H and/or ¹⁵O to reduce the use of fossil fuels. Therefore, the release of carbon dioxide during the preparation process may be reduced. ¹⁴C is produced by a reaction: ¹⁴N+¹n→¹⁴C+¹H in the presence of cosmic rays, ³H is produced by a reaction: ¹n+³He→³H+¹H in the presence of cosmic rays, and ¹⁵O is produced by removing a neutron from ¹⁶O by a gamma ray (e.g., from a lightning) (¹⁶O+γ →¹⁵O+¹n). ¹⁴C interacts with oxygen in atmosphere to produce carbon dioxide and participates in natural carbon cycle. Therefore, species that exchange carbon dioxide directly or indirectly in nature (e.g. plants) contain small amounts of ¹⁴C.

The isotopic polymer of the present disclosure can be formed into a composition alone or in combination with other materials. The composition can be used in a variety of fields to reduce the release of carbon dioxide during preparation processes.

Another aspect of the present disclosure provides a composition comprising the isotopic polymer described above.

In some embodiments, the composition may further include a non-isotopic polymer, a wavelength converting material, a filler, or a combination thereof.

The “non-isotopic polymer” of the present disclosure include polymers that do not include ¹⁴C, ³H, ¹⁵O and/or other isotopes therein. In some embodiments, a non-isotopic polymer may comprise a polymer formed by polymerizing one or more monomers having a main structure represented by one of Formulae 1 to 7, and which does not include ¹⁴C, ³H, ¹⁵O and/or other isotopes in the main structure.

Non-limiting examples of the non-isotopic polymer of the present disclosure may include, but are not limited to, silicone resins, modified organosilicone resins (e.g., acrylate-modified organosilicone resins), epoxy resins, bisphenol epoxy resins, alicyclic epoxy resins, phenolic resins, urea resins, melamine resins, polyvinyl urethane resins, unsaturated polyesters, poly diallyl phthalates, polyimides, acrylates (e.g., poly(methyl methacrylate) (PMMA)), phenolic polymers, and/or acrylate-modified polyurethanes, or a combination thereof.

In some embodiments, the wavelength converting material may include quantum dots and/or phosphors. The quantum dots may include, for example, yellow quantum dots, green quantum dots, red quantum dots, and/or blue quantum dots. In some embodiments, the phosphors may include, for example, nitrogen oxide phosphors, sulfide phosphors, silicate phosphors, fluoride phosphors, aluminate phosphors, borate phosphors, phosphate phosphors and/or nitride phosphors. In some embodiments, the phosphors may include, for example, yellow phosphors, green phosphors, red phosphors, and/or blue phosphors. Non-limiting examples of the green phosphors include, but are not limited to, lutetium aluminium garnet (LuAG)phosphors, sialon (B—SiAlON)phosphors, and silicate phosphors. Non-limiting examples of the red phosphors include, but are not limited to, (Sr,Ca)AlSiN₃:Eu²⁺, Ca₂Si₅N₈:Eu²⁺, Sr(LiAl₃N₄):Eu², manganese doped red fluoride phosphors (e.g., K₂GeF₆:Mn⁴⁺, K₂SiF₆:Mn⁴⁺, K₂TiF₆:Mn⁴⁺, etc.). Non-limiting examples of the blue phosphors include, but are not limited to, BaMgAl₁₀O₁₇:Eu²⁺, Sr₅(PO₄)₃Cl:Eu²⁺, KSrPO₄:Eu²⁺, and Ba₁₋ₓSrₓZrSi₃O₉:Eu²⁺.

In some embodiments, the filler may include, for example, inorganic particles, organic polymer particles, or a combination thereof. Non-limiting examples of the inorganic particles may include, but are not limited to, silicon oxides (SiO₂), titanium oxides (TiO₂), aluminium oxides, calcium carbonates, zinc oxides, a carbon black, barium sulfates, or a combination thereof. Non-limiting examples of the organic polymer particles may include, but are not limited to, polymethylmethacrylates (PMMA), polystyrenes (PS), acrylonitrile-butadiene-styrene copolymers (ABS), polyurethanes (PU), or a combination thereof.

The isotopic polymer of the present disclosure, and compositions comprising the same, can be used in a wide variety of fields. In some embodiments, the isotopic polymer of the present disclosure may be applied to structural materials for chip devices, e.g. as packaging materials, cup wall materials, substrate materials for chip devices.

Another aspect of the present disclosure provides a chip device, whose materials include the isotopic polymer of the present disclosure. In some embodiments, the isotopic polymer of the present disclosure can be further mixed with other materials and applied to structural materials of chip devices according to application requirements.

In some embodiments, the chip device includes a substrate, at least one chip disposed on the substrate, and a package structure encapsulating the chip, wherein the package structure and/or the substrate comprises one or more isotopic polymers of the aforementioned disclosure. In some embodiments, the chip may be, for example, a semiconductor chip, an integrated circuit chip, a light emitting diode chip, or a photo-detection chip. In some embodiments, the package structure includes an encapsulant disposed on the substrate to cover the chip and a portion of a substrate surface, wherein the encapsulant materials may include an isotopic polymer of the present disclosure, or a mixture of an isotopic polymer of the present disclosure and other materials. In the case that the chip device is a light emitting device, for example, the chip may be a light emitting diode (LED) chip, and the encapsulant may be further mixed with a wavelength converting material (e.g., quantum dots and/or phosphors) to emit the desired color light, but the present disclosure is not limited thereto. In some embodiments, the package structure may include a sidewall structure disposed on the substrate and surrounding the chip, wherein the sidewall structure and the substrate together form an accommodating area, and the encapsulant and the chip are disposed within the accommodating area. In some embodiments, materials of the sidewall structure and/or the substrate may include the isotopic polymer of the present disclosure, further, a suitable filler may be selected to be blended with the isotopic polymer of the present disclosure as desired. In the case that the chip device is a light emitting device, the chip may be a light emitting diode chip. In order to increase an efficiency of light emission of the chip device, materials of the sidewall structure and/or the substrate may include a mixture of the isotopic polymer of the present disclosure and a filler having a reflective property to reflect light. The filler having a reflective property may be, for example, one of titanium dioxides, aluminium oxides, silicon oxides, zinc oxides, magnesium carbonates, magnesium hydroxides, calcium carbonates, calcium hydroxides, calcium silicates, magnesium silicates, barium titanates, barium sulfates, alumina, alumina, zirconia, or a combination thereof, but the present disclosure is not limited thereto. When the chip device is an LED chip device and applied to an LED display device, in order to increase the contrast of the LED display device, materials of the sidewall structure and/or the substrate may be a black resin, wherein the black resin includes an isotopic polymer of the present disclosure and a filler having a light-absorbing property. When the chip device is an integrated circuit chip device and a photo-detection chip device, in some embodiments, the encapsulant, the sidewall structure may be a black resin, wherein the black resin includes an isotopic polymer of the present disclosure and a filler having a light-absorbing property. The filler having a light-absorbing property may be, for example, a carbon black, a black dye, or a graphite, but the present disclosure is not limited thereto.

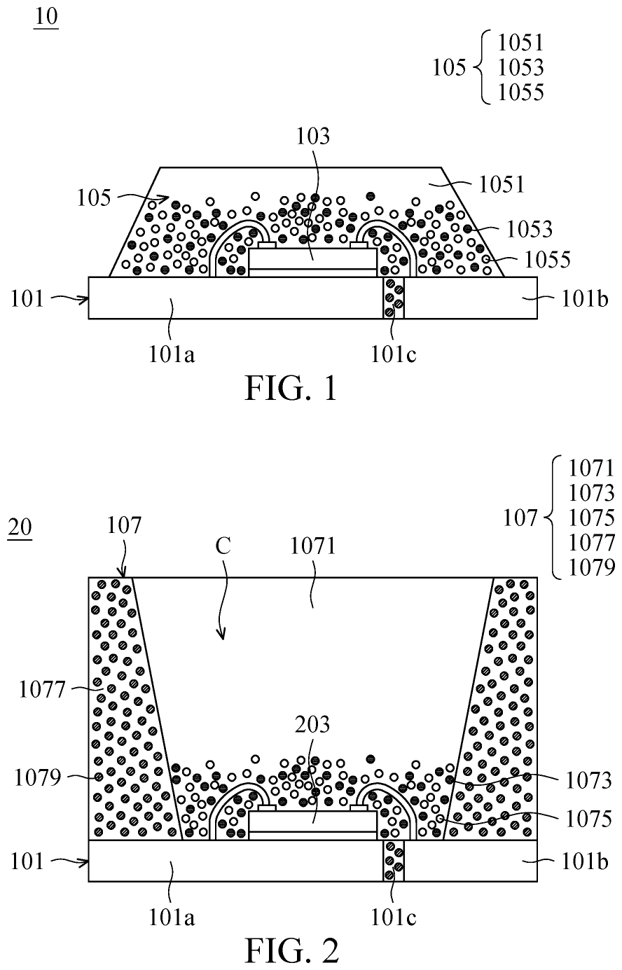

There may be various chip devices. For the sake of illustration, the isotopic polymers of the present disclosure may be applied to structural materials of the chip devices, such as packaging materials, the cup wall materials, the substrate materials of the chip devices as shown in FIGS. 1 to 6, but the present disclosure is not limited thereto.

FIG. 1 is a cross-sectional schematic view of a chip device 10 according to an embodiment of the present disclosure. As shown in FIG. 1, the chip device 10 includes a substrate 101, a chip 103 disposed on the substrate 101, and a package structure 105 encapsulating the chip 103. The substrate 101 includes a first conductive portion 101a and a second conductive portion 101b, and an insulating portion 101c disposed between the first conductive portion 101a and the second conductive portion 101b. The chip 103 is electrically connected to the first conductive portion 101a and the second conductive portion 101b.

Materials of the package structure 105 and/or materials of the substrate 101 may include the isotopic polymers of the present disclosure. The package structure 105 may include an encapsulant 1051 disposed on the substrate 101, wherein the encapsulant 1051 covers the chip 103 and upper surfaces of the first conductive portion 101a and the second conductive portion 101b of the substrate 101. Materials of the encapsulant 1051 and/or materials of the insulating portion 101c of the substrate 101 may include one or more isotopic polymers of the present disclosure. In some embodiments, the materials of the encapsulant 1051 and/or the insulating portion 101c of the substrate 101 may further include a non-isotopic polymer, a wavelength converting material, a filler, or a combination thereof.

Non-limiting examples of the non-isotopic polymer of the present disclosure may include, but are not limited to, silicone resins, modified organosilicone resins (e.g., acrylate-modified organosilicone resins), epoxy resins, bisphenol epoxy resins, alicyclic epoxy resins, phenolic resins, urea resins, melamine resins, polyvinyl urethane resins, unsaturated polyesters, poly diallyl phthalates, polyimides, acrylates (e.g., poly(methyl methacrylate) (PMMA)), phenolic polymers, and/or acrylate-modified polyurethanes, or a combination thereof.

In some embodiments, the chip device 10 may be a light emitting device. In the light emitting device, the chip 103 may include a light emitting diode (LED) chip. Non-limiting examples of the light emitting diode chip may include, but is not limited to, a sub-millimeter light emitting diode (mini LED) chip and a micro light emitting diode (micro LED) chip. In addition, the light emitting diode chip may include, but is not limited to, a UV LED, a blue LED, a green LED, or a red LED. In some embodiments, the package structure 105 of the light emitting device may include a mixture of an encapsulant 1051 and a wavelength converting material 1053 to emit the desired color light, but the present disclosure is not limited thereto. In some embodiments, the wavelength converting material 1053 may be omitted. The wavelength converting material 1053 may be dispersed homogeneously or inhomogeneity in the encapsulant 1051. The wavelength converting material 1053 may include quantum dots and/or phosphors excited by a blue LED or UV LED. Non-limiting examples of quantum dots and/or phosphors have been described above and will not be repeated herein.

In some embodiments, the package structure 105 may further include a filler 1055, but the present disclosure is not limited thereto. In some embodiments, the filler 1055 may be omitted. The filler 1055 may be dispersed homogeneously or inhomogeneity in the encapsulant 1051. The filler 1055 may include inorganic particles, organic polymer particles, or a combination thereof. Non-limiting examples of inorganic particles and organic polymer particles have been described above and will not be repeated herein. In the case that the chip device 10 is a light emitting device, the filler 1055 may be used to scatter or refract light emitted from the light emitting diode.

FIG. 2 is a cross-sectional schematic view of a chip device 20 according to an embodiment of the present disclosure. As shown in FIG. 2, the chip device 20 includes a substrate 101, a chip 203 disposed on the substrate 101, and a package structure 107 encapsulating the chip 203.

The substrate 101 and the chip 203 of the chip device 20 are substantially the same as the substrate 101 and the chip 103 of the chip device 10 except for the package structure 107, so the structure of the package structure 107 of the chip device 20 is further described herein.

As shown in FIG. 2, the package structure 107 includes a sidewall structure 1077 and an encapsulant 1071. The sidewall structure 1077 is disposed on the substrate 101 and surrounding the chip 203. The sidewall structure 1077 and the substrate 101 together form an accommodating area C. The chip 203 is disposed in the accommodating area C. The encapsulant 1071 is disposed on the substrate 101 and is disposed in the accommodating area C to cover the chip 203.

Material of the package structure 107 and/or materials of the insulating portion 101c of the substrate 101 may include the isotopic polymer of the present disclosure. The materials of the package structure 107 may include one or more isotopic polymers of the present disclosure. The one or more isotopic polymers of the present disclosure may be included in the encapsulant 1071 and/or the material of the sidewall structure 1077 of the package structure 107, and the encapsulant 1071 and/or the materials of the sidewall structure 1077 of the package structure 107 may optionally further include a non-isotopic polymer. In some embodiments, one of the encapsulant 1071 and the sidewall structure 1077 of the package structure 107 may include one or more isotopic polymers of the present disclosure and optionally further include a non-isotopic polymer, while the other may not include the isotopic polymers of the present disclosure and include only a non-isotopic polymer. Non-limiting examples of the non-isotopic polymer have been described above and will not be repeated herein. The isotopic polymers and/or non-isotopic polymers in the encapsulant 1071 and the sidewall structure 1077 may be the same or different from each other. Similarly, the insulating portion 101c may include one or more isotopic polymers of the present disclosure, and optionally further include a non-isotopic polymer. In some embodiments, the materials in the insulating portion 101c are the same as that in the sidewall structure 1077.

In some embodiments, the chip device 20 may be a light emitting device, wherein the chip 203 includes a light emitting diode chip. Non-limiting examples of the light emitting diode chip have been described above and will not be repeated herein. In some embodiments, the package structure 107 may include a mixture of an encapsulant 1071 containing the isotopic polymer of the present disclosure and a wavelength converting material 1073, but the present disclosure is not limited thereto. In some embodiments, the wavelength converting material 1073 may be omitted. The wavelength converting material 1073 may be dispersed homogeneously or inhomogeneity in the encapsulant 1071. The wavelength converting material 1073 may include quantum dots and/or phosphors. Non-limiting examples of quantum dots and/or phosphors have been described above and will not be repeated herein.

In some embodiments, the package structure 107 may further include a first filler 1075 and a second filler 1079, but the present disclosure is not limited thereto. The first filler 1075 may be dispersed homogeneously or inhomogeneity in the encapsulant 1071. The second filler 1079 may be dispersed homogeneously or inhomogeneity in the sidewall structure 1077. In some embodiments, at least one of the first filler 1075 and the second filler 1079 may be omitted. The first filler 1075 and the second filler 1079 may include inorganic particles, organic polymer particles, or a combination thereof. Non-limiting examples of inorganic particles and organic polymer particles have been described above and will not be repeated herein. The first filler 1075 and the second filler 1079 may be the same or different from each other. In some embodiments, the insulating portion 101c of the substrate 101 may further include the second filler 1079. For example, in the case that the chip device 20 is a light emitting device, the sidewall structure 1077 and the insulating portion 101c of the substrate 101 may be a white resin for reflecting the light and increasing an efficiency of the light emission, wherein the second filler 1079 may be, for example, a white reflective material, such as titanium dioxide (TiO₂) blended with the isotopic polymer of the present disclosure, but the present disclosure is not limited thereto. In addition, the first filler 1075 may be dispersed homogeneously or inhomogeneity in the encapsulant 1071 for scattering or refracting the light emitted from the light emitting diode.

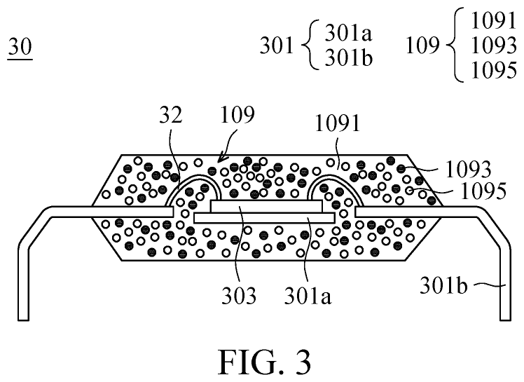

FIG. 3 is a cross-sectional schematic view of a chip device 30 according to an embodiment of the present disclosure. As shown in FIG. 3, the chip device 30 includes a substrate 301, a chip 303 disposed on the substrate 301, and a package structure 109 disposed on the substrate 301 for encapsulating the chip 303. The substrate 301 includes a lead frame 301a for supporting the chip 303, and includes a plurality of pins 301b around the lead frame 301a to serve for electrically connecting the chip 303 to the outside. The pins 301b include a metallic material. Non-limiting examples of metallic materials may include, but are not limited to, copper, silver, aluminium, nickel, other known suitable materials, or any combination of the foregoing. The chip 303 may be electrically connected to the pin 301b via the conductor wire 32. The package structure 109 may encase the lead frame 301a, the chip 303, the lead wires 32, and a portion of the pins 301b. A portion of the pins 301b may be exposed from the package structure 109 for electrically connecting the chip 303 to the outside.

In some embodiments, the chip 303 may be an integrated circuit chip. The package structure 109 may include an encapsulant 1091 and a wavelength converting material 1093. In some embodiments, the encapsulant 1091 may be a mixture comprising the isotopic polymer of the present disclosure and a filler 1095 having a light-absorbing property, which may be a black resin, and the filler 1095 may be, for example, a carbon black, a black dye, or a graphite.

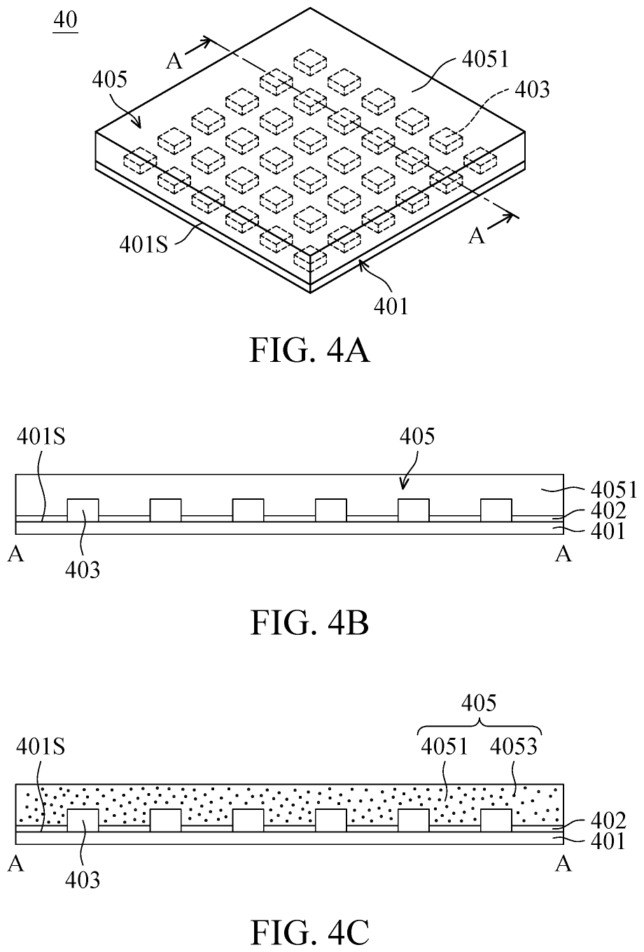

FIG. 4A is a cross-sectional schematic view of a chip device 40 according to an embodiment of the present disclosure. FIG. 4B is a cross-sectional schematic view of a chip device 40 according to FIG. 4A of an embodiment of the present disclosure. As shown in FIGS. 4A and 4B, the chip device 40 includes a substrate 401, a plurality of chips 403 disposed on the substrate 401, and a package structure 405 disposed on the substrate 401 for encapsulating the chips 403. The substrate 401 includes an upper surface 401S. The chips 403 may be disposed on the upper surface 401S of the substrate 401. In some embodiments, the substrate 401 is a circuit board.

In some embodiments, the chip device 40 may be a light-emitting device, and the chip 403 may include a light-emitting diode (LED) chip, a sub-millimeter light-emitting diode (mini LED) chip, a micro light-emitting diode (micro LED) chip, and the like, or a combination thereof, but the present disclosure is not limited thereto. The light emitting diode chip may be a UV LED, a blue LED, a green LED, a red LED, etc.

In some embodiments, as shown in FIG. 4B, the package structure 405 includes an encapsulant 4051 containing the isotopic polymer of the present disclosure for encapsulating the light-emitting diode chips 403 and covering the upper surface 401S of the substrate 401. In some embodiments, a reflective layer 402 may be formed on the upper surface 401S of the substrate 401 for reflecting light, wherein materials of the reflective layer 402 may include, for example, a mixture of a reflective material such as titanium oxide (TiO₂) and one or more isotopic polymers of the present disclosure, but the present disclosure is not limited thereto.

FIG. 4C is a cross-sectional schematic view of a chip device 40 according to FIG. 4A of another embodiment of the present disclosure. As shown in FIG. 4C, in some embodiments, the package structure 405 may include a mixture of an encapsulant 4051 containing the isotopic polymer of the present disclosure and a wavelength converting material 4053 to emit a desired color light, but the present disclosure is not limited thereto. Taking an example of a white light emitting device used in the backlighting of a display device, the light emitting diode chip 403 may emit a blue light, and the wavelength converting material 4053 may include, for example, a yellow phosphor.

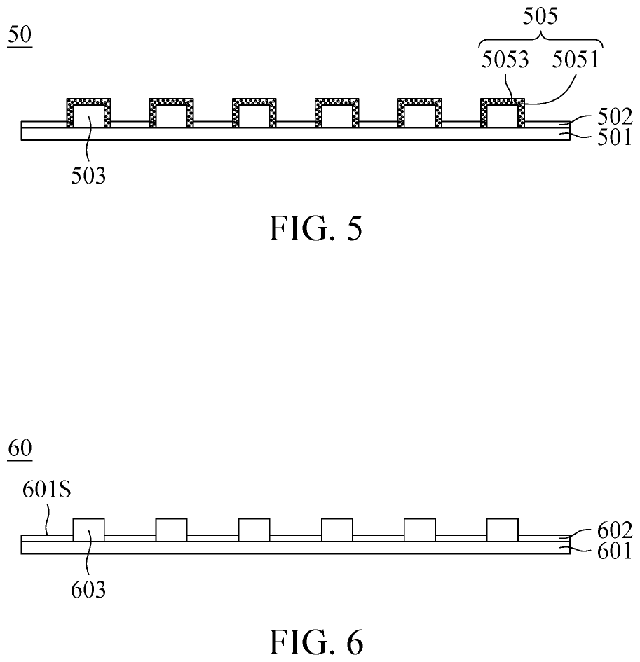

FIG. 5 is a cross-sectional schematic view of a chip device 50 according to an embodiment of the present disclosure. As shown in FIG. 5, the chip device 50 includes a substrate 501, a plurality of chips 503 disposed on the substrate 501, and a package structure 505 disposed on the substrate 501 for encapsulating the chips 503. The package structure 505 may encapsulate a top and side surfaces of the light-emitting diode chips 503 to form a chip scale package (CSP). The package structure 505 may include a mixture of an encapsulant 5051 containing an isotopic polymer of the present disclosure and a wavelength converting material 5053 to emit a desired color light, but the present disclosure is not limited thereto. In some embodiments, a reflective layer 502 may be formed on the substrate 501 for reflecting light, wherein the material of the reflective layer 502 may include, for example, a mixture of a reflective material such as titanium oxide (TiO₂) and one or more isotopic polymers of the present disclosure, but the present disclosure is not limited thereto. The substrate 501, the reflective layer 502, and the chip 503 in the chip device 50 are substantially the same as the substrate 401, the reflective layer 402, and the chip 403 in the chip device 40, except that one package structure 505 encapsulates one chip 503, and therefore will not be repeated herein.

In the case that the chip device 50 is a light emitting device, the chip 503 may be a flip-chip LED.

FIG. 6 is a cross-sectional schematic view of a chip device 60 according to an embodiment of the present disclosure. As shown in FIG. 6, the chip device 60 includes a substrate 601 and a plurality of chips 603 disposed on an upper surface 601S of the substrate 601. In some embodiments, a shading layer 602 may be formed on the upper surface 601S of the substrate 601. In some embodiments, the shading layer 602 may include a black resin, wherein the black resin may include a mixture of the isotopic polymer of the present disclosure and a filler having a light-absorbing property. The filler having a light-absorbing property may be, for example, a carbon black, a black dye, or a graphite, but the present disclosure is not limited thereto. In the case that the chip device is a micro light emitting diode (Micro LED) display device, the chip 603 includes a plurality of red Micro LED chips, green Micro LED chips, and blue Micro LED chips. The shading layer 602 increases the contrast of the Micro LED display device.

In order to make the foregoing and other purposes, features, and advantages of the present disclosure more readily apparent, the following are examples of preparations of some of the isotopic polymers of the present disclosure. However, the following examples and comparative examples are for illustrative purposes only and should not be construed as limitations on implementations of the present disclosure.

### Example 1

Mixing 5.5 g of a silicone resin formed from monomers represented by Formula A, and 4.5 g of a bio-based epoxy resin formed from monomers represented by Formula B to formed a mixture. The mixture was heated to form 10 g of polymer represented by Formula C as an isotopic polymer 1, wherein the isotopes ¹⁴C, ³H and/or ¹⁵O in the isotopic polymer 1 were present at 33 wt %.

### Example 2

Mixing 3.6 g of bio-based epoxy resins formed from monomers represented by Formula D and 6.4 g of bio-based epoxy resins formed from monomers represented by Formula B to formed a mixture. The mixture was heated to form 10 g of polymer represented by Formula E as isotopic polymer 2, wherein the isotopes ¹⁴C, ³H and/or ¹⁵O in the isotopic polymer 2 were present at 57 wt %.

Formulae A, B, C, D, and E are shown below, wherein n in Formula C is an integer selected from 1 to 1,000,000 and m in Formula E is an integer selected from 1 to 1,000,000.

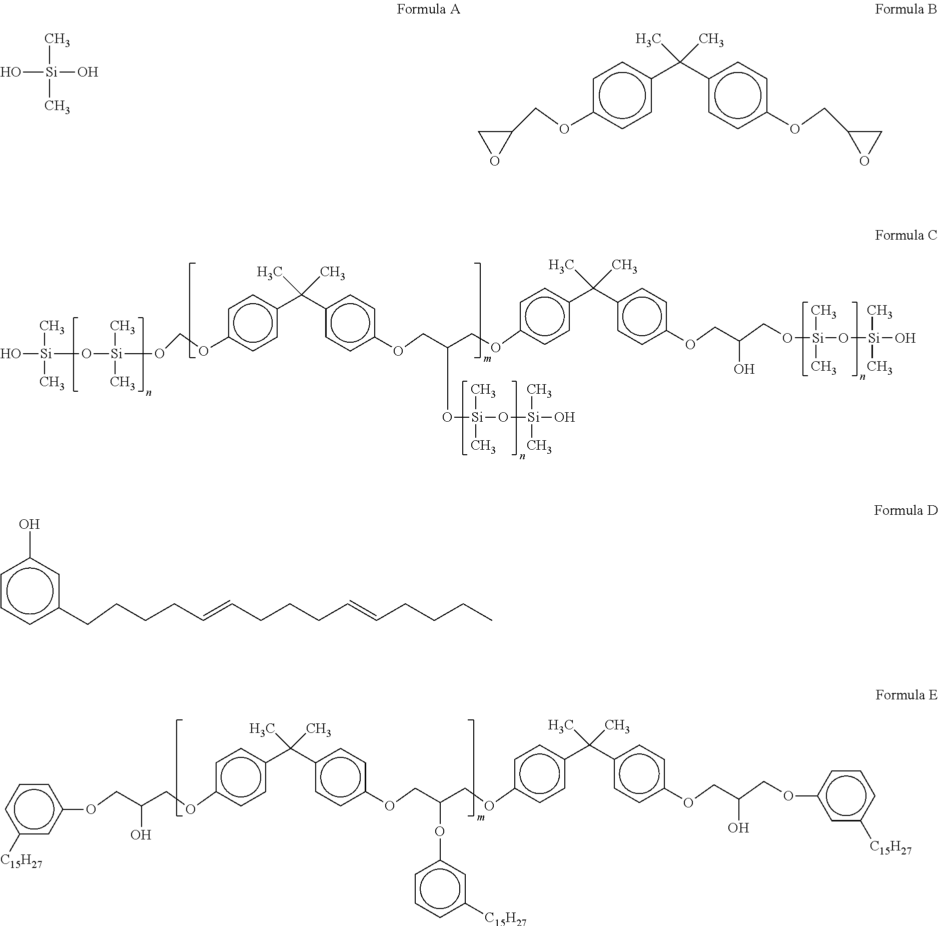

Evaluation of carbon dioxide emissions during the preparation of isotopic polymers of the examples:

Carbon dioxide reduction during the preparation of the isotopic polymers is estimated based on the isotope content in the isotopic polymers of the examples, and the results of which are shown in Table 1 below.

TABLE 1

| Number | Carbon dioxide Reduction (%) |
|---|---|
| Isotopic polymer 1 | 33% |
| Isotopic polymer 2 | 57% |

Evaluation of isotope contents and decaying age of isotopic polymers of the examples:

The isotope contents in the isotopic polymers of the examples are measured by an isotope ratio mass spectrometer and calculated according to the decay law, N=N₀*(1/2)/T, wherein No is the number of nuclei of isotopes at an initial time (t=0), N is the number of nuclei of the remaining isotopes after a decay time, t is the decay time, and T is the half-life of the isotopes. The decaying age of the isotopic polymers of the examples of the present disclosure are calculated and the results are shown in Table 2 below.

TABLE 2

| | | Isotope | |
|---|---|---|---|
| | | Content | Decaying |
| Number | Isotope | (wt %) | Age (year) |
| Example 1: | ³H | 1.2% | 9525 |
| Isotopic polymer 1 | ¹⁴C | 31.6% | |
| | ¹⁵O | 0.2% | |
| Example 2: | ³H | — | 4576 |
| Isotopic polymer 2 | ¹⁴C | 57% | |
| | ¹⁵O | — | |

As can be seen from Table 2 above, the isotopic polymer 1 and the isotopic polymer 2 of the examples have a decaying age of respective 9525 and 4576 years, which are less than 50,000 years, which indicates that the isotopic polymer 1 and the isotopic polymer 2 do have isotopes in them. In some embodiments, the isotopic polymers of the present disclosure include bio-based materials derived from natural plants. The isotopes are from carbon dioxide, methane, and oxygen in the atmosphere, and are incorporated into the monomers by photosynthesis or respiration. According to Table 1 and Table 2, the isotopic polymer 1 contains about 33% isotopes, which corresponds to a reduction in carbon dioxide emission energy of approximately 33%. The isotopic polymer 2 contains about 57% of isotopes, which corresponds to a reduction in carbon dioxide emission energy of approximately 57%. Specifically, in the case of isotopic polymer 2, the isotopic polymer 2 containing about 57% isotopes means that 57% of the isotope content is from the atmosphere and does not consume excess carbon dioxide. The non-isotopes in the isotopic polymer 2 only consumes about 43% of carbon dioxide emission energy. This means that according to Cradle to Gate, 1 kg of epoxy resin normally releases about 3.02 kg of carbon dioxide. However, 1 kg of isotopic polymer 1 of the present disclosure releases only about 2 kg of carbon dioxide because it contains about 33% isotopes, and 1 kg of isotopic polymer 2 of the present disclosure releases only about 1.3 kg of carbon dioxide because it contains about 57% isotopes.

### Evaluation of Physical Properties of the Examples and Comparative Examples

A bisphenol epoxy resin having a structure represented by Formula B was used as Comparative Example 1. An alicyclic epoxy resin having a structure represented by Formula F was used as Comparative Example 2. A silicone resin formed from monomers represented by Formula A was used as Comparative Example 3. A hardness tester was used to measure hardness (Shore Hardness) of Examples and Comparative Examples 1-3. Transmittances of Examples and Comparative Examples 1-3 at 450 nm, 550 nm, 630 nm, and 950 nm was measured by a visible spectrophotometer. The results are shown in Table 3 below.

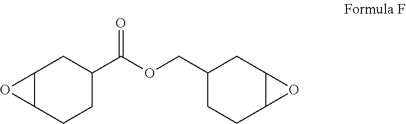 [SMILES: O=C(OCC1CCC2OC2C1)C1CCC2OC2C1]

TABLE 3

| Number | 450 nm | 550 nm | 630 nm | 950 nm |
|---|---|---|---|---|
| Comparative Example 1 | 77.5% | 79.4% | 80.2% | 82.2% |
| Comparative Example 2 | 75.6% | 79.6% | 80.9% | 82.5% |
| Comparative Example 3 | 79.3% | 81.0% | 81.7% | 83.0% |
| Example 1 | 58.0% | 72.5% | 74.6% | 77.5% |
| Example 2 | 74.8% | 78.5% | 79.4% | 81.1% |

As can be seen from the results shown in Table 3, the transmittances of Example 1 and Example 2 of the present disclosure in the range of 550 nm to 950 nm is similar to that of Comparative Example 1 to Comparative Example 3. It can be seen that the embodiments disclosed herein can maintain a desired visible light transmittance while reducing carbon dioxide emissions during their preparation.

Several embodiments are outlined above so that those having ordinary knowledge in the art to which the present disclosure belongs can better understand the perspective of the embodiments of this disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of this disclosure, and that they can make various changes, substitutions, and replacements without violating the spirit and scope of this disclosure. Therefore, the scope of protection of this disclosure is defined by the scope of the claim attached hereto. In addition, although several preferred embodiments are disclosed in the present disclosure, they are not intended to limit this disclosure.

References to features, benefits, or similar terms throughout the specification are not intended to imply that all features and benefits that can be realized using the present disclosure should or can be realized in any single embodiment of the present disclosure. Conversely, terms involving features and benefits are taken to mean that particular features, benefits, or characteristics described in combination with the embodiments are included in at least one embodiment of the present disclosure. Thus, the discussion of features and benefits and similar terms throughout the specification may, but does not necessarily, represent the same embodiments.

Furthermore, the features, benefits, and characteristics described in the present disclosure may be combined in any suitable manner in one or more embodiments. According to the description herein, those having ordinary knowledge in the art to which the present disclosure belongs will realize that the present disclosure can be implemented without one or more of particular features or benefits of a particular embodiment. In other instances, additional features and benefits may be shown in some embodiments while they may not be shown in all embodiments of the present disclosure.

What is claimed is:

1. An isotopic polymer comprising a silicone resin, an aromatic polymer, a modified silicone resin, a halogenated polysilane, an epoxy resin, or a combination thereof, wherein at least part of ¹²C, ¹H and/or ¹⁶O in the isotopic polymer is replaced with ¹⁴C, ³H and/or ¹⁵O, and a decaying age of the isotopic polymer is less than 50,000 years.

2. The isotopic polymer as claimed in claim 1, wherein the isotopic polymer is formed by polymerizing at least one isotopic monomer having a main structure represented by one of the following Formulae 1 to 7: 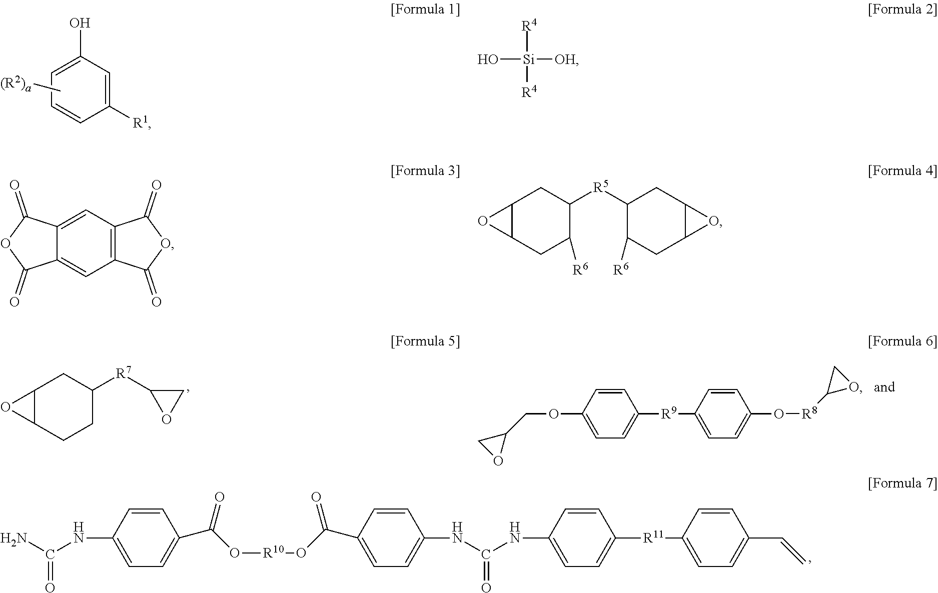
wherein R¹ is a C₁-C₃₀ alkyl group, a C₂-C₃₀ alkenyl group, or a C₂-C₃₀ alkynyl group;
R² is OH, a C₁-C₃₀ alkyl group, an amine group, a C₁-C₃₀ alkyl group substituted with an amine group, or a C₂-C₃₀ alkenyl group;
a is an integer selected from 1 to 4;
R⁴ is a phenyl group, a phenyl group substituted with a C₁-C₃₀ alkyl group, or a C₁-C₃₀ alkyl group;
R⁵ is —COOCH₂— or a C₁-C₃₀ alkylene group;
R⁶ is a C₁-C₃₀ alkyl group;
R⁷ is a C₁-C₂₀ alkylene group;
R⁸ is a nitrogen-containing linking group or a C₁-C₂₀ alkylene group;
R⁹ is a sulfur-containing linking group or a C₁-C₂₀ alkylene group;
R¹⁰ is a C₁-C₂₀ alkylene group;
R¹¹ is an oxy group, a sulfur-containing linking group, or a C₁-C₂₀ alkylene group,
wherein at least one R² is selected from a C₂-C₂₀ alkenyl group, and R² is the same as or different from each other when a is greater than or equal to 2, and
at least part of ¹²C, ¹H and/or ¹⁶O in the main structure of the isotopic polymer is replaced with ¹⁴C, ³H and/or ¹⁵O.

3. The isotopic polymer as claimed in claim 2, comprising at least one isotopic repeating unit, wherein the at least one isotopic repeating unit has a repeating unit main structure represented by one of the following Formulae 8 to 12: 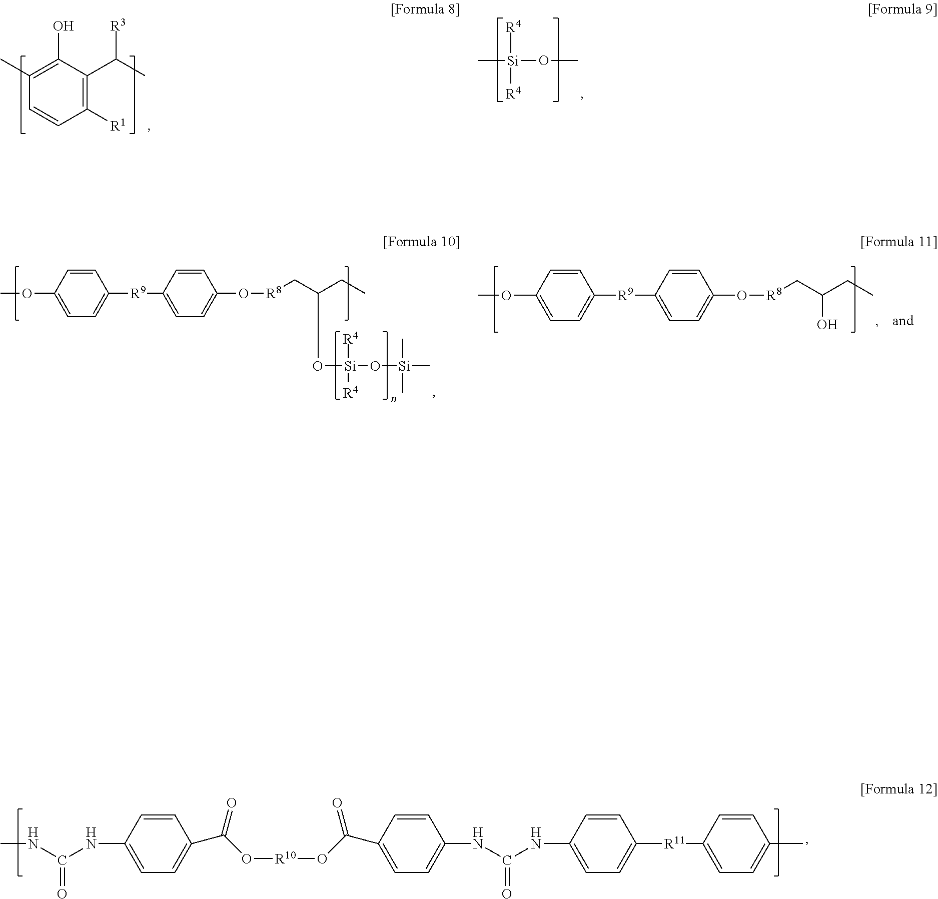
wherein R³ is a C₁-C₂₉ alkyl group, R¹, R⁴, R⁸, R⁹, R¹⁰, and R¹¹ are defined in claim 2, and at least part of ¹²C, ¹H and/or ¹⁶O in the repeating unit main structure of the isotopic repeating unit is replaced with 14° C., ³H and/or ¹⁵O.

4. The isotopic polymer as claimed in claim 2, wherein the isotopic polymer is formed by polymerizing the isotopic monomer having a main structure represented by Formula 2 and the isotopic monomer having a main structure represented by Formula 6, and has a main structure represented by the following Formula I: 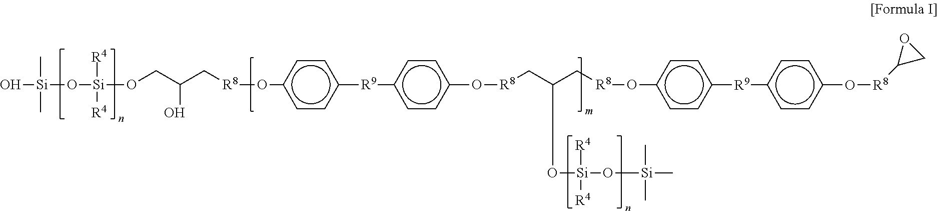
wherein n is an integer selected from 1 to 1,000,000;
m is an integer selected from 1 to 1,000,000;
R⁴, R⁸, and R⁹ are defined in claim 2, and at least part of ¹²C, ¹H and/or ¹⁶O in the main structure is replaced with ¹⁴C, ³H and/or ¹⁵O.

5. The isotopic polymer as claimed in claim 4, wherein at least part of ¹²C in R⁴ is replaced with ¹⁴C.

6. The isotopic polymer as claimed in claim 2, wherein the isotopic polymer is formed by polymerizing the isotopic monomer having a main structure represented by Formula 1 and the isotopic monomer having a main structure represented by Formula 6, and has a main structure represented by the following Formula II: 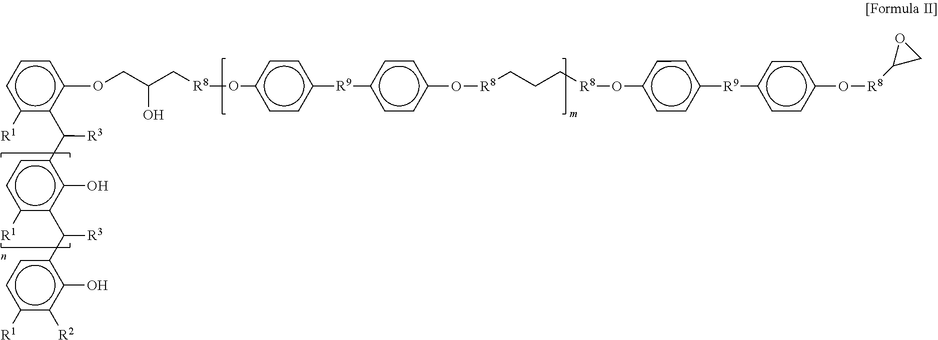
wherein n is an integer selected from 1 to 1,000,000;
m is an integer selected from 1 to 1,000,000;
R¹, R⁸ and R⁹ are defined in claim 2, and at least part of ¹²C, ¹H and/or ¹⁶O in the main structure is replaced with ¹⁴C, ³H and/or ¹⁵O.

7. The isotopic polymer as claimed in claim 1, wherein a sum of a proportion of the presence of ¹⁴C, a proportion of the presence of ³H, and a proportion of the presence of ¹⁵O is in a range from 0.1% to 100%.

8. The isotopic polymer as claimed in claim 7, wherein the sum of a proportion of the presence of ¹⁴C, a proportion of the presence of ³H, and a proportion of the presence of ¹⁵O is in a range from 0.5% to 75%.

9. The isotopic polymer as claimed in claim 1, wherein a proportion of the presence of ¹⁴C is greater than a proportion of the presence of ³H and/or a proportion of the presence of ¹⁵O.

10. A composition comprising an isotopic polymer, wherein the isotopic polymer comprises a silicone resin, an aromatic polymer, a modified silicone resin, a halogenated polysilane, an epoxy resin, or a combination thereof, and at least part of ¹²C, H and/or ¹⁶O in the isotopic polymer is replaced with ¹⁴C, ³H and/or ¹⁵O, and the decaying age of the isotopic polymer is less than 50,000 years.

11. The composition as claimed in claim 10, wherein the isotopic polymer is formed by polymerizing at least one isotopic monomer having a main structure represented by one of the following Formulae 1 to 7: 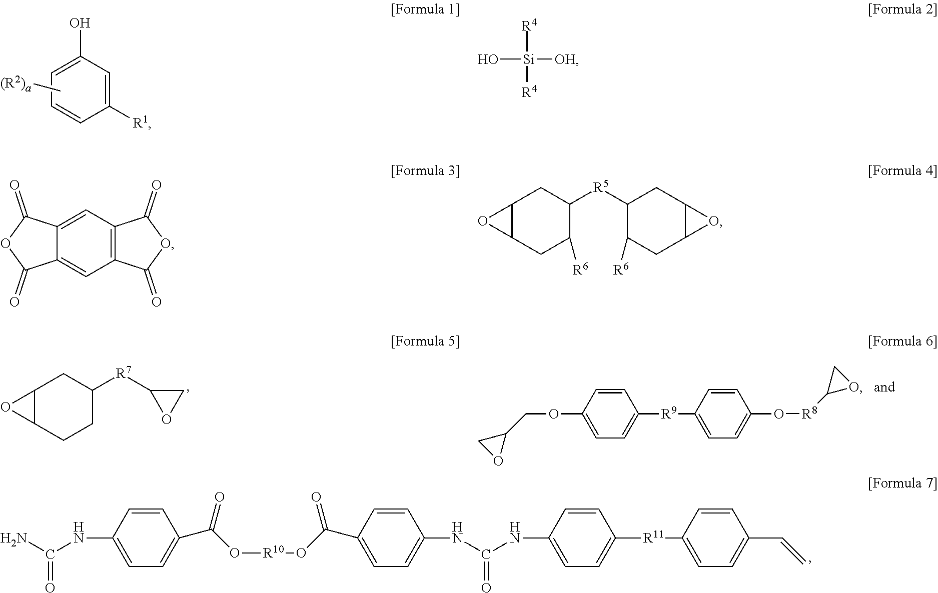
wherein R¹ is a C₁-C₃₀ alkyl group, a C₂-C₃₀ alkenyl group, or a C₂-C₃₀ alkynyl group;
R² is OH, a C₁-C₃₀ alkyl group, an amine group, a C₁-C₃₀ alkyl group substituted with an amine group, or a C₂-C₃₀ alkenyl group;
a is an integer selected from 1 to 4;
R⁴ is a phenyl group, a phenyl group substituted with a C₁-C₃₀ alkyl group, or a C₁-C₃₀ alkyl group;
R⁵ is —COOCH₂— or a C₁-C₃₀ alkylene group;
R⁶ is a C₁-C₃₀ alkyl group;
R⁷ is a C₁-C₂₀ alkylene group;
R⁸ is a nitrogen-containing linking group or a C₁-C₂₀ alkylene group;
R⁹ is a sulfur-containing linking group or a C₁-C₂₀ alkylene group;
R¹⁰ is a C₁-C₂₀ alkylene group;
R¹¹ is an oxy group, a sulfur-containing linking group, or a C₁-C₂₀ alkylene group,
wherein at least one R² is selected from a C₂-C₂₀ alkenyl group, and R² is the same as or different from each other when a is greater than or equal to 2, and
at least part of ¹²C, ¹H and/or ¹⁶O in the main structure of the isotopic polymer is replaced with ¹⁴C, ³H and/or ¹⁵O.

12. The composition as claimed in claim 10, wherein the isotopic polymer comprises at least one isotopic repeating unit, wherein the at least one isotopic repeating unit has a repeating unit main structure represented by one of the following Formulae 8 to 12: 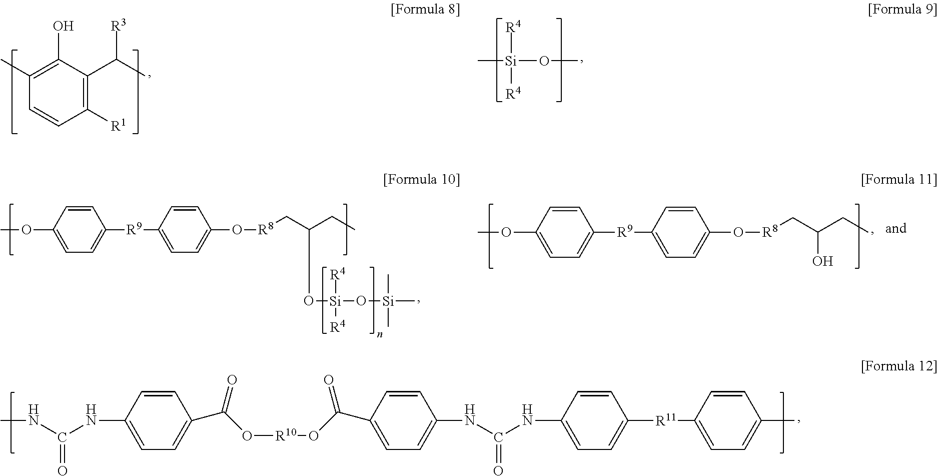
wherein R³ is a C₁-C₂₉ alkyl group, R¹, R⁴, R⁸, R⁹, R¹⁰, and R¹¹ are defined in claim 2, and at least part of ¹²C, ¹H and/or ¹⁶O in the repeating unit main structure of the isotopic repeating unit is replaced with ¹⁴C, ³H and/or ¹⁵O.

13. The composition as claimed in claim 10, wherein the composition further comprises a non-isotopic polymer, a wavelength converting material, a filler, or a combination thereof.

14. A chip device, comprising:
a substrate;
a chip disposed on the substrate; and
a package structure encapsulating the chip, wherein materials of the package structure and/or materials of the substrate comprises one or more isotopic polymers, wherein the isotopic polymer comprises a silicone resin, an aromatic polymer, a modified silicone resin, a halogenated polysilane, an epoxy resin, or a combination thereof, and at least part of ¹²C, ¹H and/or ¹⁶O in the isotopic polymer is replaced with ¹⁴C, ³H and/or ¹⁵O, and the decaying age of the isotopic polymer is less than 50,000 years.

15. The chip device as claimed in claim 14, wherein the isotopic polymer is formed by polymerizing at least one isotopic monomer having a main structure represented by one of the following Formulae 1 to 7: 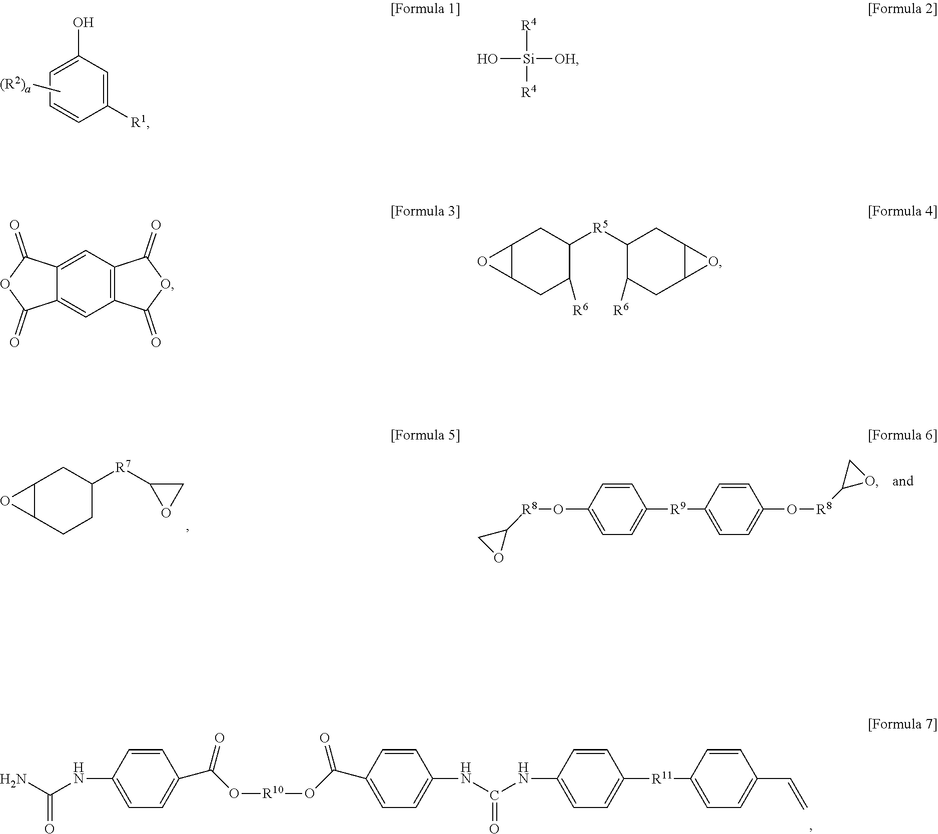
wherein R¹ is a C₁-C₃₀ alkyl group, a C₂-C₃₀ alkenyl group, or a C₂-C₃₀ alkynyl group;
R² is OH, a C₁-C₃₀ alkyl group, an amine group, a C₁-C₃₀ alkyl group substituted with an amine group, or a C₂-C₃₀ alkenyl group;
a is an integer selected from 1 to 4;
R⁴ is a phenyl group, a phenyl group substituted with a C₁-C₃₀ alkyl group, or a C₁-C₃₀ alkyl group;
R⁵ is —COOCH₂— or a C₁-C₃₀ alkylene group;
R⁶ is a C₁-C₃₀ alkyl group;
R⁷ is a C₁-C₂₀ alkylene group;
R⁸ is a nitrogen-containing linking group or a C₁-C₂₀ alkylene group;
R⁹ is a sulfur-containing linking group or a C₁-C₂₀ alkylene group;
R¹⁰ is a C₁-C₂₀ alkylene group;
R¹¹ is an oxy group, a sulfur-containing linking group, or a C₁-C₂₀ alkylene group,
wherein at least one R² is selected from a C₂-C₂₀ alkenyl group, and R² is the same as or different from each other when a is greater than or equal to 2, and
at least part of ¹²C, ¹H and/or ¹⁶O in the main structure of the isotopic polymer is replaced with ¹⁴C, ³H and/or ¹⁵O.

16. The chip device as claimed in claim 14, wherein the isotopic polymer comprises at least one isotopic repeating unit, wherein the at least one isotopic repeating unit has a repeating unit main structure represented by one of the following Formulae 8 to 12: 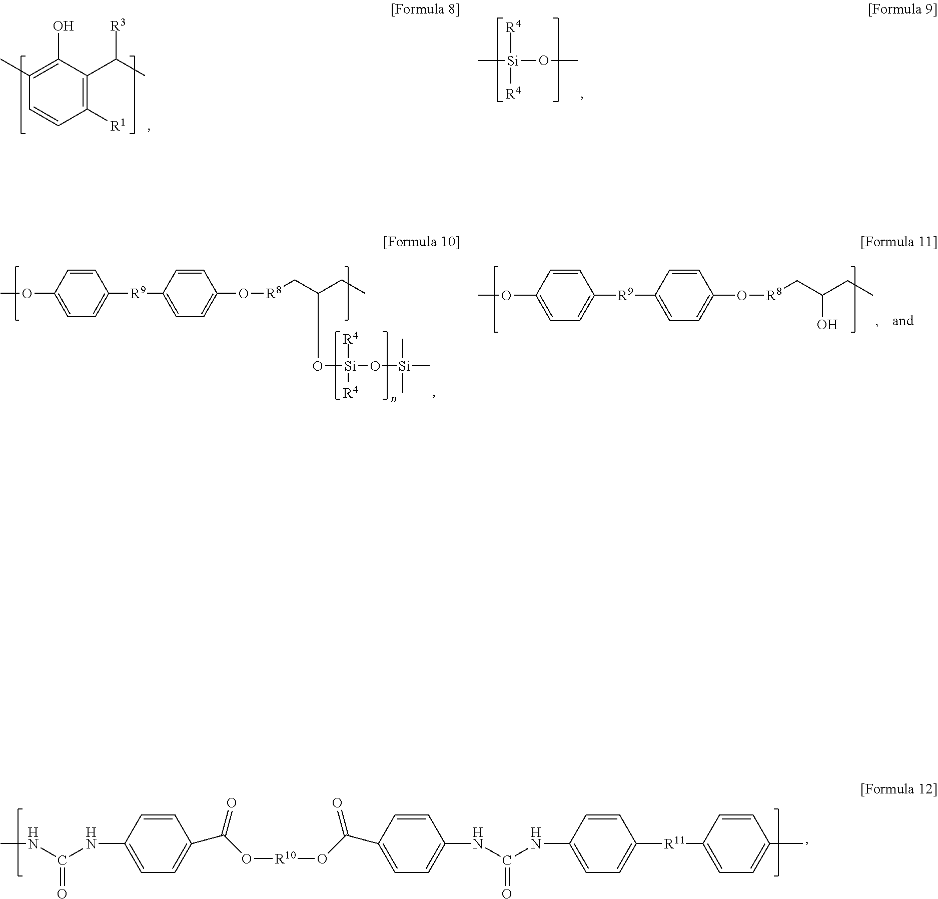
wherein R³ is a C₁-C₂₉ alkyl group, R¹, R⁴, R⁸, R⁹, R¹⁰, and R¹¹ are defined in claim 2, and at least part of ¹²C, ¹H and/or ¹⁶O in the repeating unit main structure of the isotopic repeating unit is replaced with 14° C., ³H and/or ¹⁵O.

17. The chip device as claimed in claim 14, wherein the package structure comprises an encapsulant covering the chip.

18. The chip device as claimed in claim 17, wherein the package structure comprises a sidewall structure disposed on the substrate and surrounding the chip, the sidewall structure and the substrate together form an accommodating area, and the encapsulant and the chip are disposed within the accommodating area.

19. A chip device, comprising:
a substrate;
a chip disposed on the substrate; and
a shading layer disposed on the substrate, wherein materials of the shading layer and/or materials of the substrate comprise an isotopic polymer, wherein the isotopic polymer comprises a silicone resin, an aromatic polymer, a modified silicone resin, a halogenated polysilane, an epoxy resin, or a combination thereof, and at least part of ¹²C, ¹H and/or ¹⁶O in the isotopic polymer is replaced with ¹⁴C, ³H and/or ¹⁵O, and the decaying age of the isotopic polymer is less than 50,000 years.

20. The chip device as claimed in claim 19, wherein the isotopic polymer is formed by polymerizing at least one isotopic monomer having a main structure represented by one of the following Formulae 1 to 7: 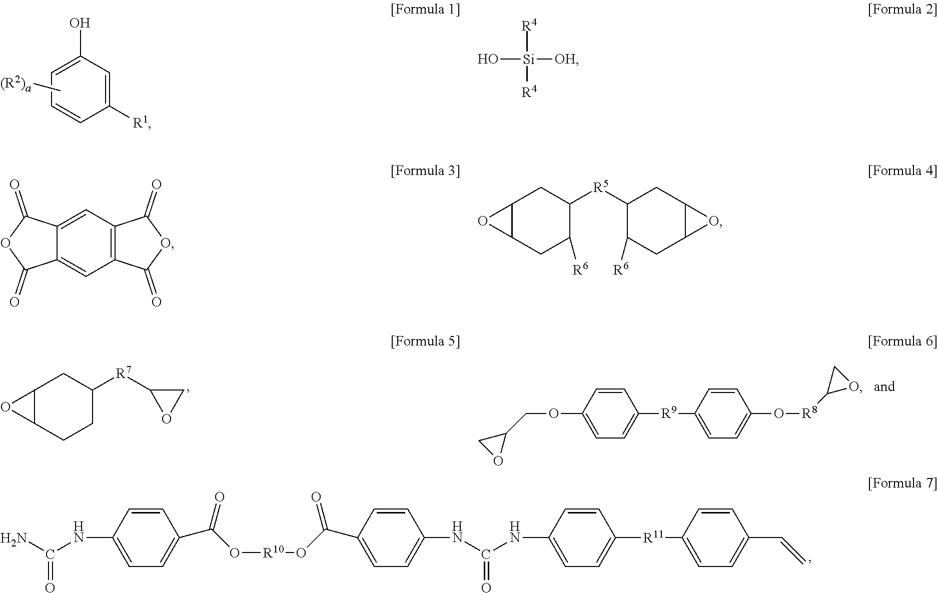
wherein R¹ is a C₁-C₃₀ alkyl group, a C₂-C₃₀ alkenyl group, or a C₂-C₃₀ alkynyl group;
R² is OH, a C₁-C₃₀ alkyl group, an amine group, a C₁-C₃₀ alkyl group substituted with an amine group, or a C₂-C₃₀ alkenyl group;
a is an integer selected from 1 to 4;
R⁴ is a phenyl group, a phenyl group substituted with a C₁-C₃₀ alkyl group, or a C₁-C₃₀ alkyl group;
R⁵ is —COOCH₂— or a C₁-C₃₀ alkylene group;
R⁶ is a C₁-C₃₀ alkyl group;
R⁷ is a C₁-C₂₀ alkylene group;
R⁸ is a nitrogen-containing linking group or a C₁-C₂₀ alkylene group;
R⁹ is a sulfur-containing linking group or a C₁-C₂₀ alkylene group;
R¹⁰ is a C₁-C₂₀ alkylene group;
R¹¹ is an oxy group, a sulfur-containing linking group, or a C₁-C₂₀ alkylene group,
wherein at least one R² is selected from a C₂-C₂₀ alkenyl group, and R² is the same as or different from each other when a is greater than or equal to 2, and
at least part of ¹²C, ¹H and/or ¹⁶O in the main structure of the isotopic polymer is replaced with ¹⁴C, ³H and/or ¹⁵O.
